(19) United States
(12) Patent Application Publication
(10) Pub. No.: US 2025/0107344 A1
(43) Pub. Date: Mar. 27, 2025

(54) DISPLAY PANEL

(71) Applicant: Samsung Display Co., Ltd., Yongin-si (KR)

(72) Inventors: MINWOO WOO, Yongin-si (KR); SOKWON NOH, Yongin-si (KR); KIHOON PARK, Yongin-si (KR); JOONHYOUNG PARK, Yongin-si (KR); SE WAN SON, Yongin-si (KR); KWANHEE LEE, Yongin-si (KR); JONGYOON LEE, Yongin-si (KR)

(21) Appl. No.: 18/778,824

(22) Filed: Jul. 19, 2024

(30) Foreign Application Priority Data
Sep. 27, 2023 (KR) 10-2023-0130110

(51) Int. Cl. H10K 59/122

(52) U.S. Cl. CPC H10K 59/122

(57) ABSTRACT

A display panel which includes a base layer, a pixel defining layer on the base layer and that has a light emitting opening, a barrier wall on the pixel defining layer and that has a barrier wall opening that overlaps the light emitting opening, and a light emitting element including an anode, an intermediate layer, and a cathode that makes contact with the barrier wall. The barrier wall opening includes a first inner surface and a third inner surface that extend in a direction parallel to a first direction, a second inner surface and a fourth inner surface that extend in a direction parallel to a second direction crossing the first direction, a first corner region, a second corner region, a third corner region, and a fourth corner region.

### CROSS-REFERENCE TO RELATED APPLICATIONS

The present application claims priority to and the benefit of Korean Patent Application No. 10-2023-0130110, filed on Sep. 27, 2023, in the Korean Intellectual Property Office, the entire disclosure of which is incorporated herein by reference.

### BACKGROUND

### 1. Field

Aspects of some embodiments of the present disclosure described herein relate to a display panel.

### 2. Description of the Related Art

Display devices, such as televisions, monitors, smart phones, tablet computers, and the like, which display images to users include a display panel that displays images. Various display panels, such as liquid crystal display panels, organic light emitting display panels, electro wetting display panels, electrophoretic display panels, and the like, are being developed.

Organic light emitting display panels may include anodes, cathodes, and emission patterns. The emission patterns may be divided from one another for respective emissive regions, and the cathodes may provide a common voltage for the respective emissive regions.

The above information disclosed in this Background section is only for enhancement of understanding of the background and therefore the information discussed in this Background section does not necessarily constitute prior art.

### SUMMARY

Aspects of some embodiments of the present disclosure described herein relate to a display panel, and for example, to a display panel with relatively improved display quality.

Aspects of some embodiments of the present disclosure include a display panel with relatively improved display quality, in which light emitting elements are formed without the use of a metal mask.

According to some embodiments, a display panel includes a base layer, a pixel defining layer on the base layer and that has a light emitting opening, a barrier wall on the pixel defining layer and that has a barrier wall opening that overlaps the light emitting opening, and a light emitting element including an anode, an intermediate layer, and a cathode that makes contact with the barrier wall. According to some embodiments, the barrier wall opening includes a first inner surface and a third inner surface that extend in a direction parallel to a first direction, a second inner surface and a fourth inner surface that extend in a direction parallel to a second direction crossing the first direction, a first corner region that connects the first inner surface and the second inner surface, a second corner region that connects the second inner surface and the third inner surface, a third corner region that connects the third inner surface and the fourth inner surface, and a fourth corner region that connects the fourth inner surface and the first inner surface.

According to some embodiments, each of the first to fourth corner regions may include a plurality of sub-inner surfaces, and an interior angle formed by the first inner surface and at least one sub-inner surface adjacent to the first inner surface among the plurality of sub-inner surfaces may be 180 degrees or more.

According to some embodiments, in a plan view, the first corner region may have an arc shape that connects the first inner surface and the second inner surface.

According to some embodiments, the first corner region may include a first sub-inner surface that extends from the first inner surface and a second sub-inner surface that extends from the first sub-inner surface and that is connected with the second inner surface.

According to some embodiments, an interior angle formed by the first sub-inner surface and the first inner surface may be 180 degrees or more, and an interior angle formed by the second sub-inner surface and the second inner surface may be 180 degrees or more.

According to some embodiments, the first corner region may include a first sub-inner surface that extends from the first inner surface, a second sub-inner surface that extends from the first sub-inner surface, and a third sub-inner surface that extends from the second sub-inner surface and that is connected with the second inner surface.

According to some embodiments, an interior angle formed by the first sub-inner surface and the first inner surface may be 180 degrees or more, and an interior angle formed by the third sub-inner surface and the second inner surface may be 180 degrees or more.

According to some embodiments, an interior angle formed by the first sub-inner surface and the second sub-inner surface may be 90 degrees, and an interior angle formed by the second sub-inner surface and the third sub-inner surface may be 90 degrees.

According to some embodiments, the first corner region may include a first sub-inner surface that extends from the first inner surface, a second sub-inner surface that extends from the first sub-inner surface, a third sub-inner surface that extends from the second sub-inner surface, and a fourth sub-inner surface that extends from the third sub-inner surface and that is connected with the second inner surface.

According to some embodiments, an interior angle formed by the first sub-inner surface and the first inner surface may be 180 degrees or more, and an interior angle formed by the fourth sub-inner surface and the second inner surface may be 180 degrees or more.

According to some embodiments, an interior angle formed by the first sub-inner surface and the second sub-inner surface may be 90 degrees, an interior angle formed by the second sub-inner surface and the third sub-inner surface may be 90 degrees, and an interior angle formed by the third sub-inner surface and the fourth sub-inner surface may be 90 degrees.

According to some embodiments, the first to fourth inner surfaces may include protruding regions, respectively, each of which includes a plurality of sub-inner surfaces, and the plurality of sub-inner surfaces may extend in directions away from the center of the barrier wall opening.

According to some embodiments, a display panel includes a base layer, a pixel defining layer on the base layer and that has a light emitting opening, a barrier wall on the pixel defining layer and that has a barrier wall opening that overlaps the light emitting opening, and a light emitting element including an anode, an intermediate layer, and a cathode that makes contact with the barrier wall. According to some embodiments, the barrier wall opening includes a first inner surface and a third inner surface that extend in a direction parallel to a first direction, a second inner surface and a fourth inner surface that extend in a direction parallel to a second direction crossing the first direction, and corner regions that connect the first to fourth inner surfaces and extend in directions away from the center of the barrier wall opening.

According to some embodiments, the corner regions may include a first corner region that connects the first inner surface and the second inner surface, a second corner region that connects the second inner surface and the third inner surface, a third corner region that connects the third inner surface and the fourth inner surface, and a fourth corner region that connects the fourth inner surface and the first inner surface.

According to some embodiments, each of the first to fourth corner regions may include a plurality of sub-inner surfaces, and an interior angle formed by the first inner surface and at least one sub-inner surface adjacent to the first inner surface among the plurality of sub-inner surfaces may be 180 degrees or more.

According to some embodiments, in a plan view, the first corner region may have an arc shape that connects the first inner surface and the second inner surface.

According to some embodiments, the first corner region may include a first sub-inner surface that extends from the first inner surface and a second sub-inner surface that extends from the first sub-inner surface and that is connected with the second inner surface.

According to some embodiments, the first corner region may include a first sub-inner surface that extends from the first inner surface, a second sub-inner surface that extends from the first sub-inner surface, and a third sub-inner surface that extends from the second sub-inner surface and that is connected with the second inner surface.

According to some embodiments, the first corner region may include a first sub-inner surface that extends from the first inner surface, a second sub-inner surface that extends from the first sub-inner surface, a third sub-inner surface that extends from the second sub-inner surface, and a fourth sub-inner surface that extends from the third sub-inner surface and that is connected with the second inner surface.

According to some embodiments, the first to fourth inner surfaces may include protruding regions, respectively, each of which includes a plurality of sub-inner surfaces, and the plurality of sub-inner surfaces may extend in directions away from the center of the barrier wall opening.

### BRIEF DESCRIPTION OF THE DRAWINGS

The above and other aspects and features of the present disclosure will become apparent by describing in more detail aspects of some embodiments thereof with reference to the accompanying drawings.

FIG. 1A is a perspective view of a display device according to some embodiments of the present disclosure.

FIG. 1B is an exploded perspective view of the display device according to some embodiments of the present disclosure.

FIG. 2 is a sectional view of a display module according to some embodiments of the present disclosure.

FIG. 3 is a plan view of a display panel according to some embodiments of the present disclosure.

FIG. 4 is an enlarged plan view illustrating a portion of a display region of the display panel according to some embodiments of the present disclosure.

FIG. 5 is a sectional view of the display panel taken along the line I-I′ of FIG. 3 according to some embodiments of the present disclosure.

FIG. 6 is a sectional view taken along the line II-II′ of FIG. 4.

FIG. 7 is a perspective view of a first barrier wall layer of a display panel according to a comparative example.

FIG. 8 is a perspective view of a first barrier wall layer of a display panel according to some embodiments of the present disclosure.

FIG. 9 is a perspective view of a first barrier wall layer of a display panel according to some embodiments of the present disclosure.

FIG. 10 is a perspective view of a first barrier wall layer of a display panel according to some embodiments of the present disclosure.

FIG. 11 is a perspective view of a first barrier wall layer of a display panel according to some embodiments of the present disclosure.

FIG. 12 is a perspective view of a first barrier wall layer of a display panel according to some embodiments of the present disclosure.

FIG. 13 is a perspective view of a first barrier wall layer of a display panel according to some embodiments of the present disclosure.

FIG. 14 is a perspective view of a first barrier wall layer of a display panel according to some embodiments of the present disclosure.

### DETAILED DESCRIPTION

In this specification, when it is mentioned that a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure will be described with reference to the accompanying drawings.

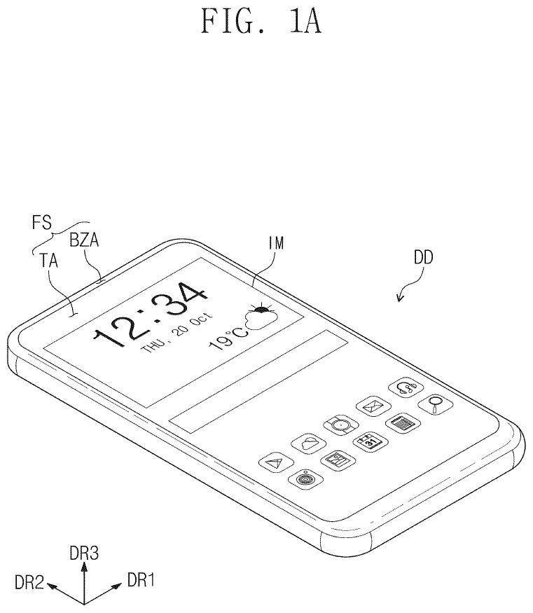

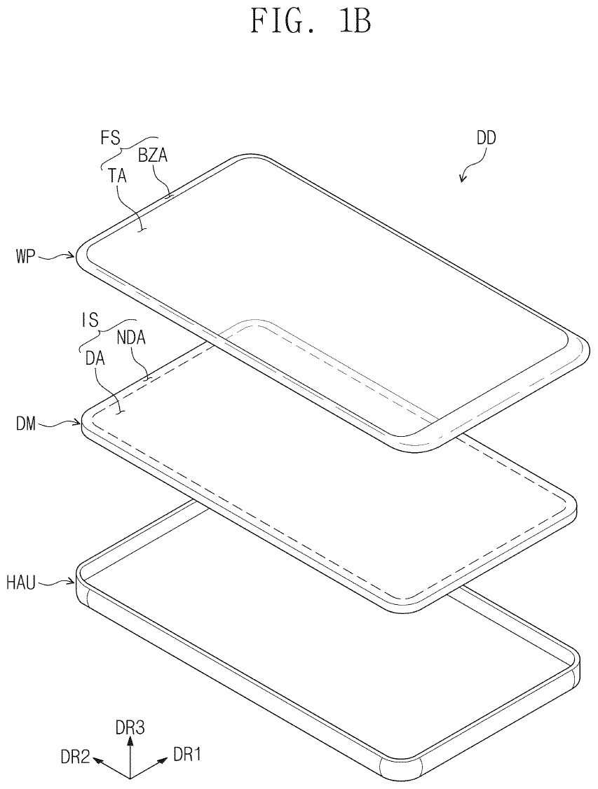

FIG. 1A is a perspective view of a display device DD according to some embodiments of the present disclosure. FIG. 1B is an exploded perspective view of the display device DD according to some embodiments of the present disclosure.

According to some embodiments, the display device DD may be a large electronic device such as a television, a monitor, or a billboard. Alternatively, the display device DD may be a small and medium-sized electronic device such as a personal computer, a notebook computer, a personal digital terminal, a car navigation unit, a game machine, a smart phone, a tablet computer, or a camera. However, this is illustrative, and the display device DD may be employed as other display devices without departing from the spirit and scope of embodiments according to the present disclosure. In FIGS. 1A and 1B, the display device DD is illustrated as a smart phone, but embodiments according to the present disclosure are not limited thereto.

Referring to FIGS. 1A and 1B, the display device DD may display an image IM in a third direction DR3 on a display surface FS parallel to a first direction DR1 and a second direction DR2. The third direction DR3 may be a normal direction of a plane defined by the first direction DR1 and the second direction DR2. The image IM may include a still image (e.g., a static image) as well as a dynamic image (e.g., video images). In FIG. 1A, a clock window and icons are illustrated as examples of the image IM. The display surface FS on which the image IM is displayed may correspond to the front surface or the display surface of the display device DD.

According to some embodiments, front surfaces (or, upper surfaces) and rear surfaces (or, lower surfaces) of members are defined based on the direction in which the image IM is displayed. The front surfaces and the rear surfaces may face away from each other in the third direction DR3, and the normal directions of the front surfaces and the rear surfaces may be parallel to the third direction DR3. Meanwhile, the directions indicated by the first to third directions DR1, DR2, and DR3 may be relative concepts and may be changed to other directions. As used herein, the expressions “when viewed from above the plane” or “in a plan view” may refer to a view from the third direction DR3.

The display device DD may include a window WP, a display module DM, and a housing HAU. The window WP and the housing HAU may be coupled with each other to form the exterior of the display device DD.

The window WP may include an optically clear insulating material. For example, the window WP may include glass or plastic. The front surface of the window WP may define the display surface FS of the display device DD. The display surface FS may include a transmissive region TA and a bezel region BZA. The transmissive region TA may be an optically clear region. For example, the transmissive region TA may be a region having a visible light transmittance of 90% (or about 90%) or more.

The bezel region BZA may be a region having a lower light transmittance than the transmissive region TA. The bezel region BZA may define the shape of the transmissive region TA. The bezel region BZA may be adjacent to the transmissive region TA and may surround the transmissive region TA. However, this is illustrative, and the bezel region BZA of the window WP may be omitted. The window WP may include at least one of an anti-fingerprint layer, a hard coating layer, or an anti-reflection layer and is not limited to any one embodiment.

The display module DM may be located under the window WP. The display module DM may be a component that substantially generates the image IM. The image IM generated by the display module DM is displayed on a display surface IS of the display module DM and visually recognized or perceived by a user from the outside through the transmissive region TA.

The display module DM may include a display region DA and a non-display region NDA. The display region DA may be a region activated depending on an electrical signal. The non-display region NDA may be adjacent to (e.g., in a periphery or outside a footprint of) the display region DA. The non-display region NDA may surround the display region DA. The non-display region NDA may be a region covered by the bezel region BZA and may not be visible from the outside.

The housing HAU may be coupled with the window WP. The housing HAU may be coupled with the window WP to provide an inner space. The display module DM may be accommodated in the inner space.

The housing HAU may include a material having a relatively high rigidity. For example, the housing HAU may include glass, plastic, or metal, or may include a plurality of frames and/or plates formed of a combination of the aforementioned materials. The housing HAU may stably protect components of the display device DD accommodated in the inner space from external impact.

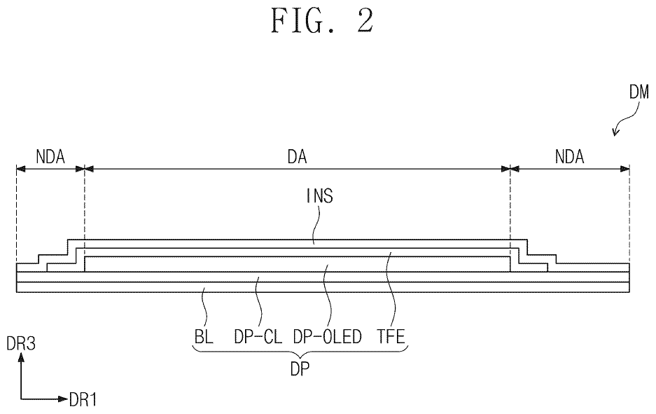

FIG. 2 is a sectional view of the display module DM according to some embodiments of the present disclosure.

Referring to FIG. 2, the display module DM may include a display panel DP and an input sensor INS. According to some embodiments, the display device DD (refer to FIG. 1A) according to some embodiments of the present disclosure may further include a protective member located on the lower surface of the display panel DP or an anti-reflection member and/or a window member located on the upper surface of the input sensor INS.

The display panel DP may be an emissive display panel. However, this is illustrative, and embodiments according to the present disclosure are not particularly limited thereto. For example, the display panel DP may be an organic light emitting display panel or an inorganic light emitting display panel. An emissive layer in the organic light emitting display panel may include an organic luminescent material. An emissive layer in the inorganic light emitting display panel may include quantum dots, quantum rods, or micro LEDs. Hereinafter, it will be illustrated that the display panel DP is an organic light emitting display panel.

The display panel DP may include a base layer BL, and a circuit element layer DP-CL, a display element layer DP-OLED, and a thin film encapsulation layer TFE that are located on the base layer BL. The input sensor INS may be directly located on the thin film encapsulation layer TFE. As used herein, the expression “component A is directly located on component B” means that an adhesive layer is (or in some embodiments, other components or layers are) not located between component A and component B.

The base layer BL may include at least one plastic film. The base layer BL may be a flexible substrate and may include a plastic substrate, a glass substrate, a metal substrate, or an organic/inorganic composite substrate. The display region DA and the non-display region NDA described with reference to FIG. 1B may be identically defined in the base layer BL.

The circuit element layer DP-CL may include at least one insulating layer and a circuit element. The insulating layer may include at least one inorganic layer and at least one organic layer. The circuit element includes signal lines and a pixel drive circuit.

The display element layer DP-OLED may include a barrier wall and a light emitting element. The light emitting element may include an anode, an intermediate layer, and a cathode.

The thin film encapsulation layer TFE may include a plurality of thin films. Some of the thin films may be arranged to relatively improve optical efficiency, and the other thin films may be arranged to protect organic light emitting diodes.

The input sensor INS obtains coordinate information of an external input. The input sensor INS may have a multi-layer structure. The input sensor INS may include a single conductive layer or multiple conductive layers. In addition, the input sensor INS may include a single insulating layer or multiple insulating layers. The input sensor INS may sense the external input in a capacitive type. However, this is illustrative, and embodiments according to the present disclosure are not limited thereto. For example, according to some embodiments, the input sensor INS may sense the external input using an electromagnetic induction method or a pressure sensing method. Meanwhile, according to some embodiments of the present disclosure, the input sensor INS may be omitted.

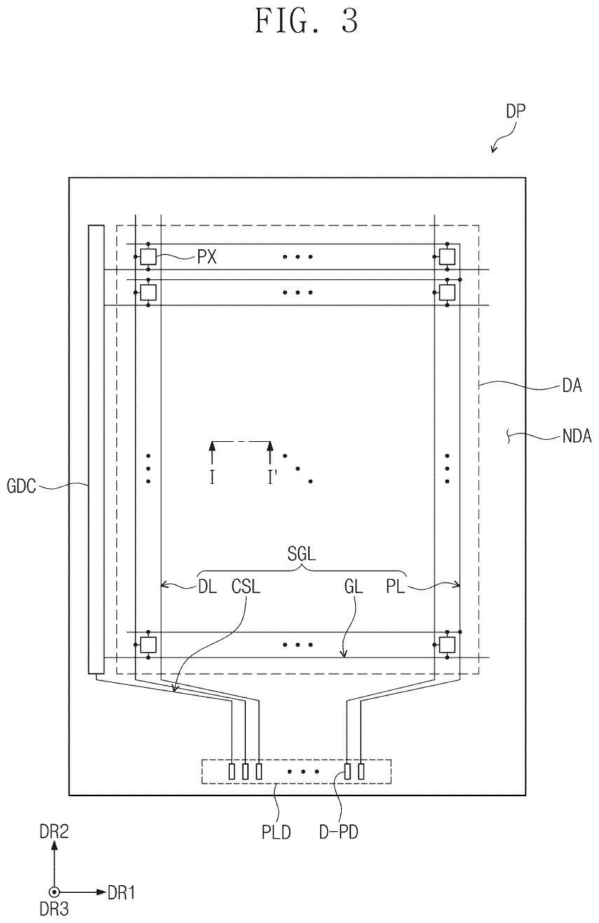

FIG. 3 is a plan view of the display panel DP according to some embodiments of the present disclosure.

Referring to FIG. 3, the display panel DP may include the display region DA and the non-display region NDA around the display region DA. The display panel DP may include pixels PX and signal lines SGL electrically connected to the pixels PX. The display panel DP may include a drive circuit GDC and a pad part PLD. The display region DA and the non-display region NDA may be distinguished from each other depending on whether the pixels PX are arranged. The pixels PX may be located in the display region DA. The drive circuit GDC and the pad part PLD may be located in the non-display region NDA.

The pixels PX may be arranged in the first direction DR1 and the second direction DR2. The pixels PX may include a plurality of pixel rows that extend in the first direction DR1 and that are arranged in the second direction DR2 and a plurality of pixel columns that extend in the second direction DR2 and that are arranged in the first direction DR1.

The signal lines SGL may include gate lines GL, data lines DL, a power line PL, and a control signal line CSL. Each of the gate lines GL may be connected to a corresponding pixel among the pixels PX, and each of the data lines DL may be connected to a corresponding pixel among the pixels PX. The power line PL may be electrically connected to the pixels PX. The control signal line CSL may be connected to the drive circuit GDC and may provide control signals to the drive circuit GDC.

The drive circuit GDC may include a gate drive circuit. The gate drive circuit may generate gate signals and may sequentially output the generated gate signals to the gate lines GL. The gate drive circuit may additionally output other control signals to the pixel drive circuit.

The pad part PLD may be a part to which a flexible circuit board is connected. The pad part PLD may include pixel pads D-PD, and the pixel pads D-PD may be pads for connecting the flexible circuit board to the display panel DP. Each of the pixel pads D-PD may be connected with a corresponding signal line among the signal lines SGL. The pixel pads D-PD may be connected to the corresponding pixels PX through the signal lines SGL. Furthermore, one pixel pad among the pixel pads D-PD may be connected to the drive circuit GDC.

In addition, the pad part PLD may further include input pads. The input pads may be pads for connecting a flexible circuit board to the input sensor INS (refer to FIG. 2). However, without being limited thereto, the input pads may be located on the input sensor INS (refer to FIG. 2) and may be connected to the pixel pads D-PD and a separate circuit board. Alternatively, the input sensor INS (refer to FIG. 2) may be omitted, and the input pads may not be additionally included.

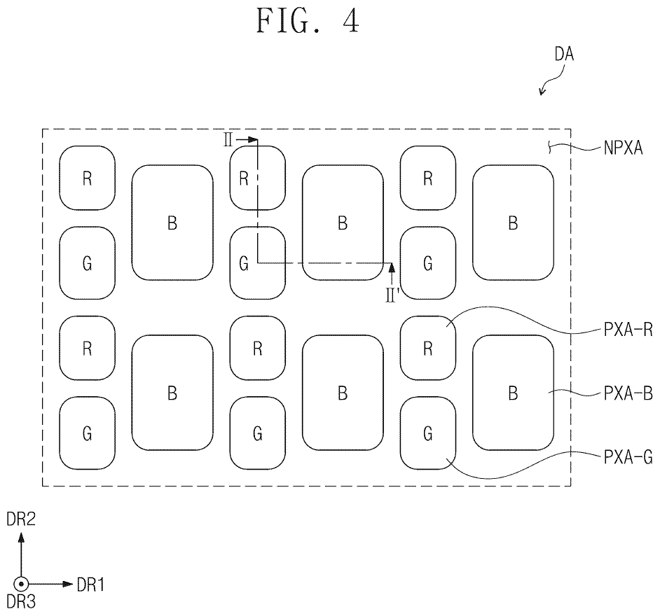

FIG. 4 is an enlarged plan view illustrating a portion of the display region DA of the display panel DP (refer to FIG. 2) according to some embodiments of the present disclosure. FIG. 4 is a plan view of the display module DM as viewed from above the display surface IS (refer to FIG. 1B) of the display module DM (refer to FIG. 1B) (e.g., when viewed in a plan view) and illustrates an arrangement of emissive regions PXA-R, PXA-G, and PXA-B.

Referring to FIG. 4, the display region DA may include the first to third emissive regions PXA-R, PXA-G, and PXA-B and a peripheral region NPXA surrounding the first to third emissive regions PXA-R, PXA-G, and PXA-B. The first to third emissive regions PXA-R, PXA-G, and PXA-B may correspond to regions through which light provided from light emitting elements is emitted. The first to third emissive regions PXA-R, PXA-G, and PXA-B may be distinguished from one another depending on the colors of light emitted toward the outside of the display module DM (refer to FIG. 2).

The first to third emissive regions PXA-R, PXA-G, and PXA-B may provide first color light, second color light, and third color light that have different colors, respectively. For example, the first color light may be red light, the second color light may be green light, and the third color light may be blue light. However, examples of the first color light, the second color light, and the third color light are not necessarily limited thereto.

Each of the first to third emissive regions PXA-R, PXA-G, and PXA-B may be defined as a region where the upper surface of an anode is exposed by a light emitting opening that will be described below. The peripheral region NPXA may set the boundaries between the first to third emissive regions PXA-R, PXA-G, and PXA-B and may prevent or reduce color mixing between the first to third emissive regions PXA-R, PXA-G, and PXA-B.

A plurality of first emissive regions PXA-R, a plurality of second emissive regions PXA-G, and a plurality of third emissive regions PXA-B may be provided. The plurality of first emissive regions PXA-R, the plurality of second emissive regions PXA-G, and the plurality of third emissive regions PXA-B may have an arrangement (e.g., a set or predetermined arrangement) in the display region DA and may be repeatedly arranged. For example, the first and second emissive regions PXA-R and PXA-G may be alternately arranged in the second direction DR2 to form a “first group”. The third emissive regions PXA-B may be arranged in the first direction DR1 to form a “second group”. The “first group” and the “second group” may be provided in plural numbers, and the “first groups” and the “second groups” may be alternately arranged in the first direction DR1.

Meanwhile, in FIG. 4, the arrangement of the first to third emissive regions PXA-R, PXA-G, and PXA-B is illustrated as an example, and without being limited thereto, the first to third emissive regions PXA-R, PXA-G, and PXA-B may be arranged in various forms. According to some embodiments, the first to third emissive regions PXA-R, PXA-G, and PXA-B may have a stripe arrangement form as illustrated in FIG. 4. Alternatively, the first to third emissive regions PXA-R, PXA-G, and PXA-B may have a PENTILE™ arrangement form or a Diamond Pixel™ arrangement form.

The first to third emissive regions PXA-R, PXA-G, and PXA-B may have various shapes when viewed from above the plane (e.g., in a plan view). For example, the first to third emissive regions PXA-R, PXA-G, and PXA-B may have a polygonal, circular, or oval shape. FIG. 4 illustrates the first to third emissive regions PXA-R, PXA-G, and PXA-B having a quadrangular shape when viewed from above the plane (e.g., in a plan view).

When viewed from above the plane (e.g., in a plan view), the first to third emissive regions PXA-R, PXA-G, and PXA-B may have the same shape, or at least some of the first to third emissive regions PXA-R, PXA-G, and PXA-B may have different shapes. Although FIG. 4 illustrates the first to third emissive regions PXA-R, PXA-G, and PXA-B having the same shape when viewed from above the plane (e.g., in a plan view), according to some embodiments, the first and third emissive regions PXA-R and PXA-B may have the same shape, and the second emissive region PXA-G may have a shape different from the shape of the first and third emissive regions PXA-R and PXA-B.

At least some of the first to third emissive regions PXA-R, PXA-G, and PXA-B may have different areas when viewed from above the plane (e.g., in a plan view). According to some embodiments, the area of the second emissive region PXA-G emitting green light may be greater than the area of the first emissive region PXA-R emitting red light and may be smaller than the area of the third emissive region PXA-B emitting blue light. However, the relative size relationship between the first to third emissive regions PXA-R, PXA-G, and PXA-B depending on the colors of emitted light is not limited thereto and may vary depending on the design of the display module DM (refer to FIG. 2). Furthermore, without being limited thereto, the first to third emissive regions PXA-R, PXA-G, and PXA-B may have the same area when viewed from above the plane (e.g., in a plan view).

Meanwhile, the shapes, areas, and arrangement of the first to third emissive regions PXA-R, PXA-G, and PXA-B of the display module DM (refer to FIG. 2) of the present disclosure may be designed in various ways depending on the colors of emitted light or the size and configuration of the display module DM (refer to FIG. 2) and are not limited to the embodiments illustrated in FIG. 4.

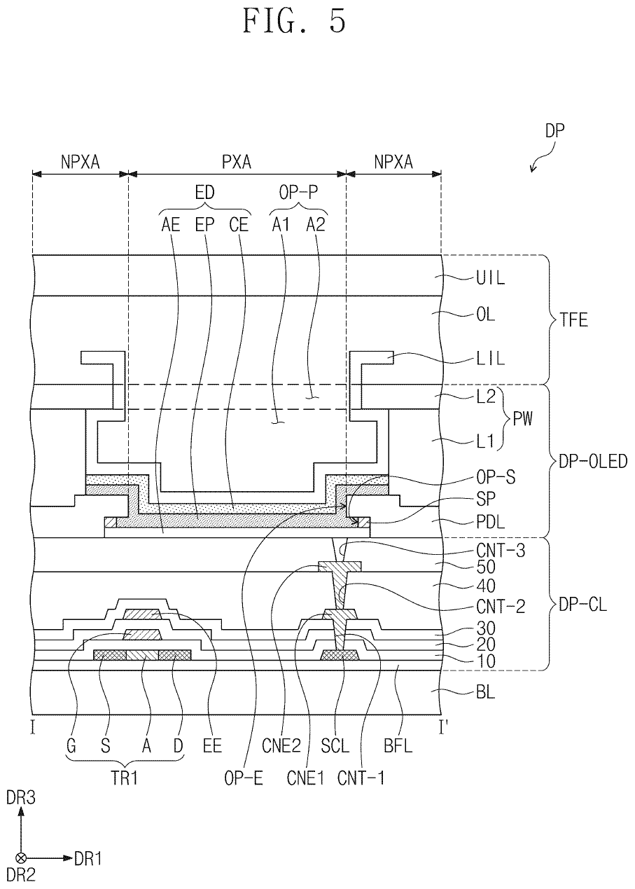

FIG. 5 is a sectional view of the display panel taken along the line I-I′ of FIG. 3 according to some embodiments of the present disclosure. In describing FIG. 5, the description will be made with reference to FIG. 2, and some repetitive descriptions of the same reference numerals may be omitted. FIG. 5 is a blowup of one emissive region PXA in the display region DA (refer to FIG. 4), and the emissive region PXA of FIG. 5 may correspond to one of the first to third emissive regions PXA-R, PXA-G, and PXA-B of FIG. 4.

Referring to FIG. 5, the display panel DP may include the base layer BL, the circuit element layer DP-CL, the display element layer DP-OLED, and the thin film encapsulation layer TFE.

The display panel DP may include a plurality of insulating layers, a semiconductor pattern, a conductive pattern, and a signal line. An insulating layer, a semiconductor layer, and a conductive layer are formed by coating, deposition, or the like. Thereafter, the insulating layer, the semiconductor layer, and the conductive layer may be selectively subjected to patterning by photolithography and etching. The semiconductor pattern, the conductive pattern, and the signal line included in the circuit element layer DP-CL and the display element layer DP-OLED may be formed by the above-described method.

The circuit element layer DP-CL may be located on the base layer BL. The circuit element layer DP-CL may include a buffer layer BFL, a transistor TR1, a signal transmission region SCL, first to fifth insulating layers 10, 20, 30, 40, and 50, an electrode EE, and a plurality of connecting electrodes CNE1 and CNE2.

The buffer layer BFL may be located on the base layer BL. The buffer layer BFL may improve the coupling force between the base layer BL and the semiconductor pattern. The buffer layer BFL may include silicon oxide layers and silicon nitride layers. The silicon oxide layers and the silicon nitride layers may be alternately stacked one above another.

The semiconductor pattern may be located on the buffer layer BFL. The semiconductor pattern may include poly-silicon. However, without being limited thereto, the semiconductor pattern may include amorphous silicon or metal oxide. In FIG. 5, a portion of the semiconductor pattern is illustrated as an example, and the semiconductor pattern may be additionally located in the plurality of emissive regions PXA-R, PXA-G, PXA-B (refer to FIG. 4). The semiconductor pattern may be arranged across the plurality of emissive regions PXA-R, PXA-G, PXA-B according to a specific rule. The semiconductor pattern may have different electrical properties depending on whether the semiconductor pattern is doped or not. The semiconductor pattern may include a first region having a high doping concentration and a second region having a low doping concentration. The first region may be doped with an N-type dopant or a P-type dopant. A P-type transistor may include a first region doped with a P-type dopant.

The first region has a higher conductivity than the second region and substantially serves as an electrode or a signal line. The second region may substantially correspond to an active (or, channel) region of the transistor. In other words, one portion of the semiconductor pattern may be the active region of the transistor, another portion may be a source or drain of the transistor, and another portion may be a conductive region.

The source S, the active region A, and the drain D of the transistor TR1 may be formed from the semiconductor pattern. In FIG. 5, a portion of the signal transmission region SCL formed from the semiconductor pattern is illustrated. According to some embodiments, the signal transmission region SCL may be connected to the drain D of the transistor TR1 when viewed from above the plane (e.g., in a plan view).

The first to fifth insulating layers 10, 20, 30, 40, and 50 may be located on the buffer layer BFL. The first to fifth insulating layers 10, 20, 30, 40, and 50 may be inorganic layers or organic layers.

The first insulating layer 10 may be located on the buffer layer BFL. The first insulating layer 10 may cover the source S, the active region A, and the drain D of the transistor TR1 and the signal transmission region SCL that are located on the buffer layer BFL. A gate G of the transistor TR1 may be located on the first insulating layer 10. The second insulating layer 20 may be located on the first insulating layer 10 and may cover the gate G. The electrode EE may be located on the second insulating layer 20. The third insulating layer 30 may be located on the second insulating layer 20 and may cover the electrode EE.

The first connecting electrode CNE1 may be located on the third insulating layer 30. The first connecting electrode CNE1 may be connected to the signal transmission region SCL through a contact hole CNT-1 penetrating the first to third insulating layers 10, 20, and 30. The fourth insulating layer 40 may be located on the third insulating layer 30 and may cover the first connecting electrode CNE1. The fourth insulating layer 40 may be an organic layer.

The second connecting electrode CNE2 may be located on the fourth insulating layer 40. The second connecting electrode CNE2 may be connected to the first connecting electrode CNE1 through a contact hole CNT-2 penetrating the fourth insulating layer 40. The fifth insulating layer 50 may be located on the fourth insulating layer 40 and may cover the second connecting electrode CNE2. The fifth insulating layer 50 may be an organic layer.

The display element layer DP-OLED may be located on the circuit element layer DP-CL. The display element layer DP-OLED may include a light emitting element ED, a sacrificial pattern SP, a pixel defining layer PDL, and a barrier wall PW. The light emitting element ED may include an anode AE (or, a first electrode), an emission pattern EP, and a cathode CE (or, a second electrode).

The anode AE may be located on the fifth insulating layer 50 of the circuit element layer DP-CL. The anode AE may be a transmissive electrode, a transflective electrode, or a reflective electrode. The anode AE may be connected to the second connecting electrode CNE2 by a connection contact hole CNT-3 defined to penetrate the fifth insulating layer 50. Accordingly, the anode AE may be electrically connected to the signal transmission region SCL through the first and second connecting electrodes CNE1 and CNE2 and may be electrically connected to a corresponding circuit element. The anode AE may include a single-layer structure or a multi-layer structure. The anode AE may include a plurality of layers including ITO and Ag. For example, the anode AE may include a layer including ITO (hereinafter, referred to as the lower ITO layer), a layer that is located on the lower ITO layer and that includes Ag (hereinafter, referred to as the Ag layer), and a layer that is located on the Ag layer and that includes ITO (hereinafter, referred to as the upper ITO layer).

The sacrificial pattern SP may be located between the anode AE and the pixel defining layer PDL. The sacrificial pattern SP may have a sacrificial opening OP-S defined therein to expose a portion of the upper surface of the anode AE. The sacrificial opening OP-S may overlap a light emitting opening OP-E that will be described below.

The pixel defining layer PDL may be located on the fifth insulating layer 50 of the circuit element layer DP-CL. The pixel defining layer PDL may have the light emitting opening OP-E defined therein. The light emitting opening OP-E may correspond to the anode AE, and the pixel defining layer PDL may expose at least a portion of the anode AE through the light emitting opening OP-E.

The light emitting opening OP-E may correspond to the sacrificial opening OP-S of the sacrificial pattern SP. According to some embodiments, the upper surface of the anode AE may be spaced apart from the pixel defining layer DPL on the section with the sacrificial pattern SP therebetween. Accordingly, damage to the anode AE in a process of forming the light emitting opening OP-E may be prevented or reduced.

When viewed from above the plane (e.g., in a plan view), the area of the light emitting opening OP-E may be smaller than the area of the sacrificial opening OP-S. That is, the inner surface of the pixel defining layer PDL that defines the light emitting opening OP-E may be closer to the center of the anode AE than the inner surface of the sacrificial pattern SP that defines the sacrificial opening OP-S. However, without being limited thereto, the inner surface of the sacrificial pattern SP that defines the sacrificial opening OP-S may be substantially aligned with the inner surface of the pixel defining layer PDL that defines the light emitting opening OP-E. In this case, the emissive region PXA may be a region of the anode AE exposed from the corresponding sacrificial opening OP-S.

The pixel defining layer PDL may include an inorganic insulating material. The pixel defining layer PDL may be located between the anode AE and the barrier wall PW and may block electrical connection between the anode AE and the barrier wall PW.

The emission pattern EP may be located on the anode AE. The emission pattern EP may include an emissive layer including a luminescent material. The emission pattern EP may further include a hole injection layer (HIL) and a hole transport layer (HTL) that are located between the anode AE and the emissive layer and may further include an electron transport layer (ETL) and an electron injection layer (EIL) that are located on the emissive layer. The emission pattern EP may be referred to as an “organic layer” or an “intermediate layer”.

The emission pattern EP may be subjected to patterning by a tip portion defined in the barrier wall PW. The emission pattern EP may be located in the light emitting opening OP-E and a barrier wall opening OP-P. The emission pattern EP may cover a portion of the upper surface of the pixel defining layer PDL exposed from the barrier wall opening OP-P.

The cathode CE may be located on the emission pattern EP. The cathode CE may be subjected to patterning by the tip portion defined in the barrier wall PW. At least a portion of the cathode CE may be located in the barrier wall opening OP-P and may make contact with the barrier wall PW in the barrier wall opening OP-P.

The cathode CE may be located on the emission pattern EP. The cathode CE may be subjected to patterning by the tip portion defined in the barrier wall PW. At least a portion of the cathode CE may be located in the barrier wall opening OP-P. The cathode CE may make contact with the inner surface S-L1 of a first barrier wall layer L1. The cathode CE may have conductivity. As long as the cathode CE is capable of having conductivity, the cathode CE may be formed of various materials such as metal, transparent conductive oxide (TCO), or a conductive polymer material. For example, the cathode CE may include silver (Ag), magnesium (Mg), lead (Pb), copper (Cu), or a compound thereof.

The barrier wall PW may be located on the pixel defining layer PDL. The barrier wall PW may have the barrier wall opening OP-P defined therein. The barrier wall opening OP-P may correspond to the light emitting opening OP-E and may expose at least a portion of the anode AE.

The barrier wall PW may have an undercut shape on the section. The barrier wall PW may include multiple layers sequentially stacked one above another, and at least one layer among the multiple layers may be recessed when compared to the other layers. Accordingly, the barrier wall PW may include the tip portion.

The barrier wall PW may include the first barrier wall layer L1 and a second barrier wall layer L2. The first barrier wall layer L1 may be located on the pixel defining layer PDL, and the second barrier wall layer L2 may be located on the first barrier wall layer L1. As illustrated in FIG. 5, the thickness of the first barrier wall layer L1 may be greater than the thickness of the second barrier wall layer L2. However, embodiments according to the present disclosure are not limited thereto.

The first barrier wall layer L1 may be relatively recessed with respect to the emissive region PXA when compared to the second barrier wall layer L2. The first barrier wall layer L1 may be undercut with respect to the second barrier wall layer L2. The portion of the second barrier wall layer L2 that protrudes from the first barrier wall layer L1 toward the emissive region PXA may be defined as the tip portion in the barrier wall PW.

The barrier wall opening OP-P defined in the barrier wall PW may include a first region A1 and a second region A2. The first barrier wall layer L1 may include the inner surface S-L1 that defines the first region A1 of the barrier wall opening OP-P, and the second barrier wall layer L2 may include an inner surface S-L2 that defines the second region A2 of the barrier wall opening OP-P. On the section, the inner surface S-L2 of the second barrier wall layer L2 may be closer to the center of the anode AE than the inner surface S-L1 of the first barrier wall layer L1. The inner surface S-L1 of the first barrier wall layer L1 may be recessed in a direction away from the center of the anode AE with respect to the inner surface S-L2 of the second barrier wall layer L2. Accordingly, the second barrier wall layer L2 protruding toward the emissive region PXA may include the tip portion.

The width of the first region A1 may be different from the width of the second region A2. The width of the first region A1 may be greater than the width of the second region A2. In this case, the second region A2 of the barrier wall opening OP-P may be a region that defines the tip portion.

Each of the first barrier wall layer L1 and the second barrier wall layer L2 may include a conductive material. For example, the conductive material may include metal, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

Although FIG. 5 illustrates an example that the inner surface S-L1 of the first barrier wall layer L1 and the inner surface surface S-L2 of the second barrier wall layer L2 are perpendicular to the upper surface of the pixel defining layer PDL, embodiments according to the present disclosure are not limited thereto. For example, the barrier wall PW may have a tapered shape or an inverted tapered shape.

The barrier wall PW may receive a drive voltage (or, a bias voltage). Accordingly, the cathode CE may be electrically connected to the barrier wall PW and may receive the drive voltage.

The thin film encapsulation layer TFE may be located on the display element layer DP-OLED. The thin film encapsulation layer TFE may include a lower inorganic encapsulation pattern LIL, an organic encapsulation film OL, and an upper inorganic encapsulation film UIL.

The lower inorganic encapsulation pattern LIL may correspond to the light emitting opening OP-E. The lower inorganic encapsulation pattern LIL may cover the cathode CE, and a portion of the lower inorganic encapsulation pattern LIL may be located in the barrier wall opening OP-P. For example, one portion of the lower inorganic encapsulation pattern LIL may be formed in the barrier wall opening OP-P, and another portion of the lower inorganic encapsulation pattern LIL may be formed on the barrier wall PW. The organic encapsulation film OL may cover the lower inorganic encapsulation pattern LIL and may provide a flat upper surface. The upper inorganic encapsulation film UIL may be located on the organic encapsulation film OL.

The lower inorganic encapsulation pattern LIL and the upper inorganic encapsulation film UIL may protect the display element layer DP-OLED from moisture/oxygen, and the organic encapsulation film OL may protect the display element layer DP-OLED from foreign matter such as dust particles.

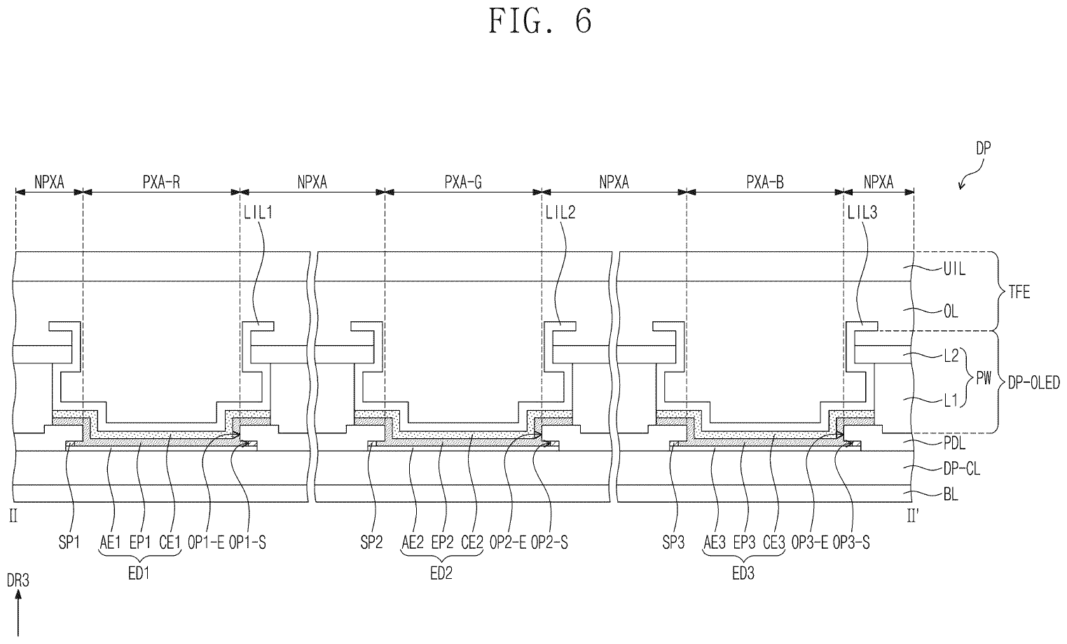

FIG. 6 is a sectional view taken along the line II-II′ of FIG. 4. FIG. 6 is an enlarged view illustrating one first emissive region PXA-R, one second emissive region PXA-G, and one third emissive region PXA-B, and the description of the emissive region PXA of FIG. 5 may be identically applied to each of the first to third emissive regions PXA-R, PXA-G, and PXA-B of FIG. 6.

Referring to FIG. 6, the display panel DP according to some embodiments may include the base layer BL, the circuit element layer DP-CL, the display element layer DP-OLED, and the thin film encapsulation layer TFE. The display element layer DP-OLED may include light emitting elements ED1, ED2, and ED3, sacrificial patterns SP1, SP2, and SP3, the pixel defining layer PDL, and the barrier wall PW.

The light emitting elements ED1, ED2, and ED3 may include the first light emitting element ED1, the second light emitting element ED2, and the third light emitting element ED3. The first light emitting element ED1 may include a first anode AE1, a first emission pattern EP1, and a first cathode CE1. The second light emitting element ED2 may include a second anode AE2, a second emission pattern EP2, and a second cathode CE2. The third light emitting element ED3 may include a third anode AE3, a third emission pattern EP3, and a third cathode CE3. The first to third anodes AE1, AE2, and AE3 may be provided in a plurality of patterns. According to some embodiments, the first emission pattern EP1 may provide red light, the second emission pattern EP2 may provide green light, and the third emission pattern EP3 may provide blue light.

First to third light emitting openings OP1-E, OP2-E, and OP3-E may be defined in the pixel defining layer PDL. The first light emitting opening OP1-E may expose at least a portion of the first anode AE1. The second light emitting opening OP2-E may expose at least a portion of the second anode AE2. The third light emitting opening OP3-E may expose at least a portion of the third anode AE3. According to some embodiments, the first emissive region PXA-R may be defined as a region of the upper surface of the first anode AE1 exposed by the first light emitting opening OP1-E. The second emissive region PXA-G may be defined as a region of the upper surface of the second anode AE2 exposed by the second light emitting opening OP2-E. The third emissive region PXA-B may be defined as a region of the upper surface of the third anode AE3 exposed by the third light emitting opening OP3-E.

The sacrificial patterns SP1, SP2, and SP3 may include the first sacrificial pattern SP1, the second sacrificial pattern SP2, and the third sacrificial pattern SP3. The first to third sacrificial patterns SP1, SP2, and SP3 may be located on the upper surfaces of the first to third anodes AE1, AE2, and AE3, respectively. First to third sacrificial openings OP1-S, OP2-S, and OP3-S overlapping the first to third light emitting openings OP1-E, OP2-E, and OP3-E may be defined in the first to third sacrificial patterns SP1, SP2, and SP3, respectively.

According to some embodiments, first to third barrier wall openings OP1-P, OP2-P, and OP3-P overlapping the first to third light emitting openings OP1-E, OP2-E, and OP3-E, respectively, may be defined in the barrier wall PW.

Each of the first to third barrier wall openings OP1-P, OP2-P, and OP3-P may include the first region A1 (refer to FIG. 5) and the second region A2 (refer to FIG. 5) described above with reference to FIG. 5. The first barrier wall layer L1 may include inner surfaces S-L1 (refer to FIG. 5) that define the first regions A1 of the first to third barrier wall openings OP1-P, OP2-P, and OP3-P, and the second barrier wall layer L2 may include inner surfaces S-L2 (refer to FIG. 5) that define the second regions A2 of the first to third barrier wall openings OP1-P, OP2-P, and OP3-P.

The first emission pattern EP1 and the first cathode CE1 may be located in the first barrier wall opening OP1-P, the second emission pattern EP2 and the second cathode CE2 may be located in the second barrier wall opening OP2-P, and the third emission pattern EP3 and the third cathode CE3 may be located in the third barrier wall opening OP3-P.

According to some embodiments, the first to third emission patterns EP1, EP2, and EP3 and the first to third cathodes CE1, CE2, and CE3 may be physically divided from one another by the second barrier wall layer L2 that forms tip portions and may be formed in the light emitting openings OP1-E, OP2-E, and OP3-E or the barrier wall openings OP1-P, OP2-P, and OP3-P.

According to the present disclosure, a plurality of first emission patterns EP1 may be subjected to patterning and deposited in pixel units by the tip portions defined in the barrier wall PW. That is, the first emission patterns EP1 may be commonly formed using an open mask, but may be easily divided in pixel units by the barrier wall PW.

In contrast, when the first emission patterns EP1 are subjected to patterning using a fine metal mask (FMM), a spacer for support that protrudes from the conductive barrier wall has to be provided to support the fine metal mask. Furthermore, the fine metal mask may be spaced, by the height of the barrier wall and the spacer, apart from a base surface on which the patterning is performed, and therefore there may be a limitation in the implementation of high resolution. In addition, because the fine metal mask is brought into contact with the spacer, foreign matter may remain on the spacer after the patterning process of the first emission patterns EP1, or the spacer may be damaged by a dent in the fine metal mask. Accordingly, a defective display panel may be formed.

According to some embodiments, because the barrier wall PW is included, the physical separation between the light emitting elements ED1, ED2, and ED3 may be easily achieved. Accordingly, current leakage or a driving error between the adjacent emissive regions PXA-R, PXA-G, and PXA-B may be prevented or reduced, and the light emitting elements ED1, ED2, and ED3 may be independently driven.

In particular, by making the plurality of first emission patterns EP1 subject to patterning without a mask in contact with an internal component in the display region DA (refer to FIG. 1B), a defect rate may be reduced, and thus the display panel DP with improved process reliability may be provided. Because the patterning is possible even without the separate spacer for support that protrudes from the barrier wall PW, the areas of the emissive regions PXA-R, PXA-G, and PXA-B may be scaled down, and thus the display panel DP capable of easily implementing high resolution may be provided.

Furthermore, in the manufacture of the large-area display panel DP, the manufacture of a large-area mask may be omitted. Accordingly, process costs may be reduced, and the display panel DP may not be affected by defects that are likely to occur in the large-area mask. Thus, the display panel DP with improved process reliability may be provided. The description of the plurality of first emission patterns EP1 may be identically applied to a plurality of second emission patterns EP2 and a plurality of third emission patterns EP3.

The thin film encapsulation layer TFE may include lower inorganic encapsulation patterns LIL1, LIL2, and LIL3, the organic encapsulation film OL, and the upper inorganic encapsulation film UIL. According to some embodiments, the lower inorganic encapsulation patterns LIL1, LIL2, and LIL3 may include the first lower inorganic encapsulation pattern LIL1, the second lower inorganic encapsulation pattern LIL2, and the third lower inorganic encapsulation pattern LIL3. The first to third lower inorganic encapsulation patterns LIL1, LIL2, and LIL3 may correspond to the first to third light emitting openings OP1-E, OP2-E, and OP3-E, respectively.

One portion of the first lower inorganic encapsulation pattern LIL1 may be formed in the first barrier wall opening OP1-P, and the other portion of the first lower inorganic encapsulation pattern LIL1 may be formed on the barrier wall PW. One portion of the second lower inorganic encapsulation pattern LIL2 may be formed in the second barrier wall opening OP2-P, and the other portion of the second lower inorganic encapsulation pattern LIL2 may be formed on the barrier wall PW. One portion of the third lower inorganic encapsulation pattern LIL3 may be formed in the third barrier wall opening OP3-P, and the other portion of the third lower inorganic encapsulation pattern LIL3 may be formed on the barrier wall PW. The first to third lower inorganic encapsulation patterns LIL1, LIL2, and LIL3 may be provided in the form of patterns spaced apart from each other.

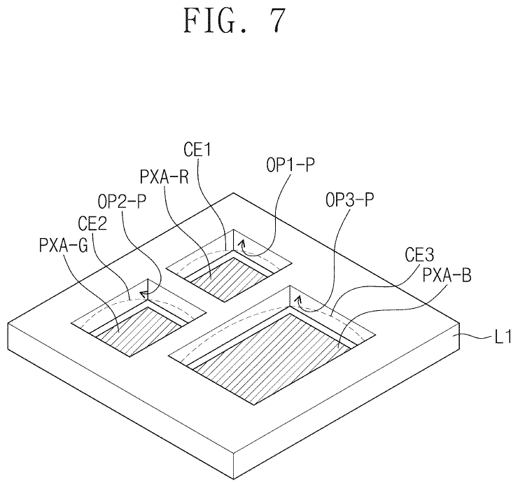

FIG. 7 is a perspective view of a first barrier wall layer L1 of a display panel according to a comparative example. FIG. 7 illustrates first regions A1 (refer to FIG. 5) of first to third barrier wall openings OP1-P, OP2-P, and OP3-P, first to third emissive regions PXA-R, PXA-G, and PXA-B, and first to third cathodes CE1, CE2, and CE3. In FIG. 7, for convenience of description, only portions of the first to third cathodes CE1, CE2, and CE3 that make contact with the first barrier wall layer L1 are illustrated by dotted lines.

Referring to FIGS. 6 and 7, the first to third cathodes CE1, CE2, and CE3 may be located on first to third emission patterns EP1, EP2, and EP3, respectively. The first to third cat6hodes CE1, CE2, and CE3 may be subjected to patterning by tip portions defined in a barrier wall PW, and at least portions of the first to third cathodes CE1, CE2, and CE3 (hereinafter, referred to as the cathodes) may be located in the first to third barrier wall openings OP1-P, OP2-P, and OP3-P and may make contact with the barrier wall PW in the first to third barrier wall openings OP1-P, OP2-P, and OP3-P (hereinafter, referred to as the barrier wall openings).

Shadow regions of the barrier wall PW may be formed by the tip portions defined in the barrier wall PW. In this case, the areas by which the cathodes CE1, CE2, and CE3 are brought into contact with the barrier wall PW so as to face toward the corners of the barrier wall openings OP1-P, OP2-P, and OP3-P may be decreased in a process in which the cathodes CE1, CE2, and CE3 are formed. Therefore, the areas by which the cathodes CE1, CE2, and CE3 are brought into contact with the barrier wall PW in the barrier wall openings OP1-P, OP2-P, and OP3-P may be decreased, and when the contact areas of the cathodes CE1, CE2, and CE3 are smaller than or equal to effective contact areas (the minimum areas by which the cathodes CE1, CE2, and CE3 have to be brought into contact with the barrier wall PW for light emission of light emitting elements ED1, ED2, and ED3), the light emitting elements ED1, ED2, and ED3 may not emit light and may have defects.

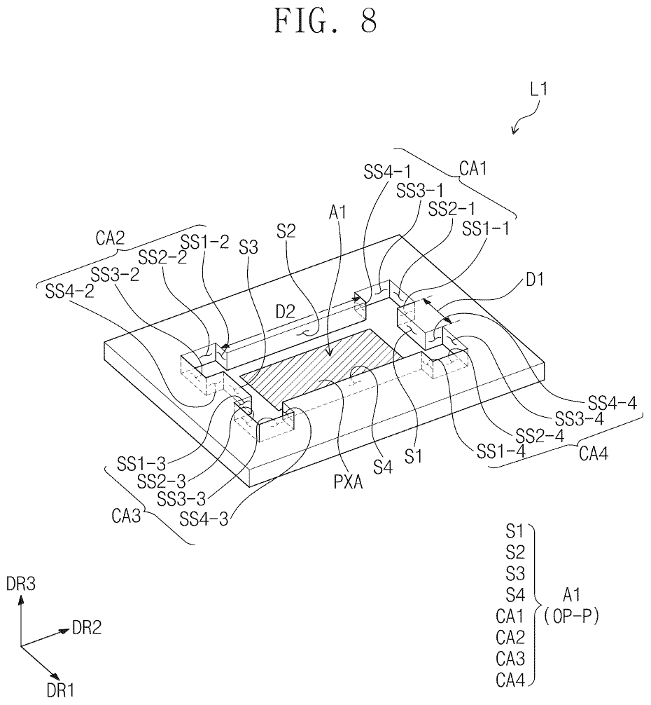

FIG. 8 is a perspective view of the first barrier wall layer L1 of the display panel DP (refer to FIG. 5) according to some embodiments of the present disclosure. For convenience of description, FIG. 8 is focused on the first region A1 of the barrier wall opening OP-P.

Referring to FIGS. 5 and 8, the first region A1 of the first barrier wall layer L1 may include a first inner surface S1, a second inner surface S2, a third inner surface S3, and a fourth inner surface S4. The first inner surface S1, the second inner surface S2, the third inner surface S3, and the fourth inner surface S4 may correspond to the inner surface S-L1 of the first barrier wall layer L1 of FIG. 5. The first inner surface S1 and the third inner surface S3 may extend in a direction parallel to the first direction DR1, and the second inner surface S2 and the fourth inner surface S4 may extend in a direction parallel to the second direction DR2.

In the present disclosure, the barrier wall opening OP-P may include corner regions CA1, CA2, CA3, and CA4. The corner regions CA1, CA2, CA3, and CA4 may connect the first to fourth inner surfaces S1, S2, S3, and S4 and may extend in directions away from the center of the barrier wall opening OP-P. The corner regions CA1, CA2, CA3, and CA4 may include the first corner region CA1, the second corner region CA2, the third corner region CA3, and the fourth corner region CA4. The first corner region CA1 may connect the first inner surface S1 and the second inner surface S2, and the second corner region CA2 may connect the second inner surface S2 and the third inner surface S3. The third corner region CA3 may connect the third inner surface S3 and the fourth inner surface S4, and the fourth corner region CA4 may connect the fourth inner surface S4 and the first inner surface S1.

Each of the first to fourth corner regions CA1, CA2, CA3, and CA4 may include a plurality of sub-inner surfaces. For example, the first to fourth corner regions CA1, CA2, CA3, and CA4 may include first sub-inner surfaces SS1-1, SS1-2, SS1-3, and SS1-4, second sub-inner surfaces SS2-1, SS2-2, SS2-3, and SS2-4, third sub-inner surfaces SS3-1, SS3-2, SS3-3, and SS3-4, and fourth sub-inner surfaces SS4-1, SS4-2, SS4-3, and SS4-4.

In detail, the first corner region CA1 may include the first sub-inner surface SS1-1, the second sub-inner surface SS2-1, the third sub-inner surface SS3-1, and the fourth sub-inner surface SS4-1. The first sub-inner surface SS1-1 may extend from the first inner surface S1 in the second direction DR2, and the second sub-inner surface SS2-1 may extend from the first sub-inner surface SS1-1 in the direction parallel to the first direction DR1 (e.g., the direction opposite to the first direction DR1). The third sub-inner surface SS3-1 may extend from the second sub-inner surface SS2-1 in the direction parallel to the second direction DR2 (e.g., the direction opposite to the second direction DR2), and the fourth sub-inner surface SS4-1 may extend from the third sub-inner surface SS3-1 in the first direction DR1. The fourth sub-inner surface SS4-1 may be connected with the second inner surface S2.

In the polygon defined by the first region A1, when viewed from above the plane (e.g., in a plan view), the interior angle formed by the first sub-inner surface SS1-1 of the first corner region CA1 and the first inner surface S1 may be 180 degrees or more, and the interior angle formed by the fourth sub-inner surface SS4-1 of the first corner region CA1 and the second inner surface S2 may be 180 degrees or more. For example, the interior angle formed by the first sub-inner surface SS1-1 of the first corner region CA1 and the first inner surface S1 and the interior angle formed by the fourth sub-inner surface SS4-1 of the first corner region CA1 and the second inner surface S2 may be 270 degrees. Hereinafter, the interior angles in FIG. 8 will be described based on the polygon.

In addition, the interior angle formed by the first sub-inner surface SS1-1 and the second sub-inner surface SS2-1 of the first corner region CA1 may be 90 degrees, the interior angle formed by the second sub-inner surface SS2-1 and the third sub-inner surface SS3-1 of the first corner region CA1 may be 90 degrees, and the interior angle formed by the third sub-inner surface SS3-1 and the fourth sub-inner surface SS4-1 of the first corner region CA1 may be 90 degrees. However, the interior angles formed by the first sub-inner surface SS1-1, the second sub-inner surface SS2-1, the third sub-inner surface SS3-1, and the fourth sub-inner surface SS4-1 are illustrative, and embodiments according to the present disclosure are not limited thereto.

The second corner region CA2 may include the first sub-inner surface SS1-2, the second sub-inner surface SS2-2, the third sub-inner surface SS3-2, and the fourth sub-inner surface SS4-2. The first sub-inner surface SS1-2 may extend from the second inner surface S2 in the direction parallel to the first direction DR1 (e.g., the direction opposite to the first direction DR1), and the second sub-inner surface SS2-2 may extend from the first sub-inner surface SS1-2 in the direction parallel to the second direction DR2 (e.g., the direction opposite to the second direction DR2). The third sub-inner surface SS3-2 may extend from the second sub-inner surface SS2-2 in the first direction DR1, and the fourth sub-inner surface SS4-2 may extend from the third sub-inner surface SS3-2 in the second direction DR2. The fourth sub-inner surface SS4-2 may be connected with the third inner surface S3.

The interior angle formed by the first sub-inner surface SS1-2 of the second corner region CA2 and the second inner surface S2 may be 180 degrees or more, and the interior angle formed by the fourth sub-inner surface SS4-2 of the second corner region CA2 and the third inner surface S3 may be 180 degrees or more. For example, the interior angle formed by the first sub-inner surface SS1-2 of the second corner region CA2 and the second inner surface S2 and the interior angle formed by the fourth sub-inner surface SS4-2 of the second corner region CA2 and the third inner surface S3 may be 270 degrees.

In addition, the interior angle formed by the first sub-inner surface SS1-2 and the second sub-inner surface SS2-2 of the second corner region CA2 may be 90 degrees, the interior angle formed by the second sub-inner surface SS2-2 and the third sub-inner surface SS3-2 of the second corner region CA2 may be 90 degrees, and the interior angle formed by the third sub-inner surface SS3-2 and the fourth sub-inner surface SS4-2 of the second corner region CA2 may be 90 degrees. However, the interior angles formed by the first sub-inner surface SS1-2, the second sub-inner surface SS2-2, the third sub-inner surface SS3-2, and the fourth sub-inner surface SS4-2 are illustrative, and embodiments according to the present disclosure are not limited thereto.

The third corner region CA3 may include the first sub-inner surface SS1-3, the second sub-inner surface SS2-3, the third sub-inner surface SS3-3, and the fourth sub-inner surface SS4-3. The first sub-inner surface SS1-3 may extend from the third inner surface S3 in the direction parallel to the second direction DR2 (e.g., the direction opposite to the second direction DR2), and the second sub-inner surface SS2-3 may extend from the first sub-inner surface SS1-3 in the first direction DR1. The third sub-inner surface SS3-3 may extend from the second sub-inner surface SS2-3 in the second direction DR2, and the fourth sub-inner surface SS4-3 may extend from the third sub-inner surface SS3-3 in the direction parallel to the first direction DR1 (e.g., the direction opposite to the first direction DR1). The fourth sub-inner surface SS4-3 may be connected with the fourth inner surface S4.

The interior angle formed by the first sub-inner surface SS1-3 of the third corner region CA3 and the third inner surface S3 may be 180 degrees or more, and the interior angle formed by the fourth sub-inner surface SS4-3 of the third corner region CA3 and the fourth inner surface S4 may be 180 degrees or more. For example, the interior angle formed by the first sub-inner surface SS1-3 of the third corner region CA3 and the third inner surface S3 and the interior angle formed by the fourth sub-inner surface SS4-3 of the third corner region CA3 and the fourth inner surface S4 may be 270 degrees.

In addition, the interior angle formed by the first sub-inner surface SS1-3 and the second sub-inner surface SS2-3 of the third corner region CA3 may be 90 degrees, the interior angle formed by the second sub-inner surface SS2-3 and the third sub-inner surface SS3-3 of the third corner region CA3 may be 90 degrees, and the interior angle formed by the third sub-inner surface SS3-3 and the fourth sub-inner surface SS4-3 of the third corner region CA3 may be 90 degrees. However, the interior angles formed by the first sub-inner surface SS1-3, the second sub-inner surface SS2-3, the third sub-inner surface SS3-3, and the fourth sub-inner surface SS4-3 are illustrative, and embodiments according to the present disclosure are not limited thereto.

The fourth corner region CA4 may include the first sub-inner surface SS1-4, the second sub-inner surface SS2-4, the third sub-inner surface SS3-4, and the fourth sub-inner surface SS4-4. The first sub-inner surface SS1-4 may extend from the fourth inner surface S4 in the first direction DR1, and the second sub-inner surface SS2-4 may extend from the first sub-inner surface SS1-4 in the second direction DR2. The third sub-inner surface SS3-4 may extend from the second sub-inner surface SS2-4 in the direction parallel to the first direction DR1 (e.g., the direction opposite to the first direction DR1), and the fourth sub-inner surface SS4-4 may extend from the third sub-inner surface SS3-4 in the direction parallel to the second direction DR2 (e.g., the direction opposite to the second direction DR2). The fourth sub-inner surface SS4-4 may be connected with the first inner surface S1.

The interior angle formed by the first sub-inner surface SS1-4 of the fourth corner region CA4 and the fourth inner surface S4 may be 180 degrees or more, and the interior angle formed by the fourth sub-inner surface SS4-4 of the fourth corner region CA4 and the first inner surface S1 may be 180 degrees or more. For example, the interior angle formed by the first sub-inner surface SS1-4 of the fourth corner region CA4 and the fourth inner surface S4 and the interior angle formed by the fourth sub-inner surface SS4-4 of the fourth corner region CA4 and the first inner surface S1 may be 270 degrees.

In addition, the interior angle formed by the first sub-inner surface SS1-4 and the second sub-inner surface SS2-4 of the fourth corner region CA4 may be 90 degrees, the interior angle formed by the second sub-inner surface SS2-4 and the third sub-inner surface SS3-4 of the fourth corner region CA4 may be 90 degrees, and the interior angle formed by the third sub-inner surface SS3-4 and the fourth sub-inner surface SS4-4 of the fourth corner region CA4 may be 90 degrees. However, the interior angles formed by the first sub-inner surface SS1-4, the second sub-inner surface SS2-4, the third sub-inner surface SS3-4, and the fourth sub-inner surface SS4-4 are illustrative, and embodiments according to the present disclosure are not limited thereto.

The interior angle formed by the first inner surface S1 and at least one sub-inner surface adjacent to the first inner surface S1 among the plurality of sub-inner surfaces may be 180 degrees or more. For example, the interior angle formed by the first inner surface S1 and the first sub-inner surface SS1-1 may be 180 degrees or more, and the interior angle formed by the first inner surface S1 and the fourth sub-inner surface SS4-4 may be 180 degrees or more. The interior angle formed by the second inner surface S2 and at least one sub-inner surface adjacent to the second inner surface S2 among the plurality of sub-inner surfaces may be 180 degrees or more. For example, the interior angle formed by the second inner surface S2 and the first sub-inner surface SS1-2 may be 180 degrees or more, and the interior angle formed by the second inner surface S2 and the fourth sub-inner surface SS4-1 may be 180 degrees or more. The interior angle formed by the third inner surface S3 and at least one sub-inner surface adjacent to the third inner surface S3 among the plurality of sub-inner surfaces may be 180 degrees or more. For example, the interior angle formed by the third inner surface S3 and the first sub-inner surface SS1-3 may be 180 degrees or more, and the interior angle formed by the third inner surface S3 and the fourth sub-inner surface SS4-2 may be 180 degrees or more. The interior angle formed by the fourth inner surface S4 and at least one sub-inner surface adjacent to the fourth inner surface S4 among the plurality of sub-inner surfaces may be 180 degrees or more. For example, the interior angle formed by the fourth inner surface S4 and the first sub-inner surface SS1-4 may be 180 degrees or more, and the interior angle formed by the fourth inner surface S4 and the fourth sub-inner surface SS4-3 may be 180 degrees or more.

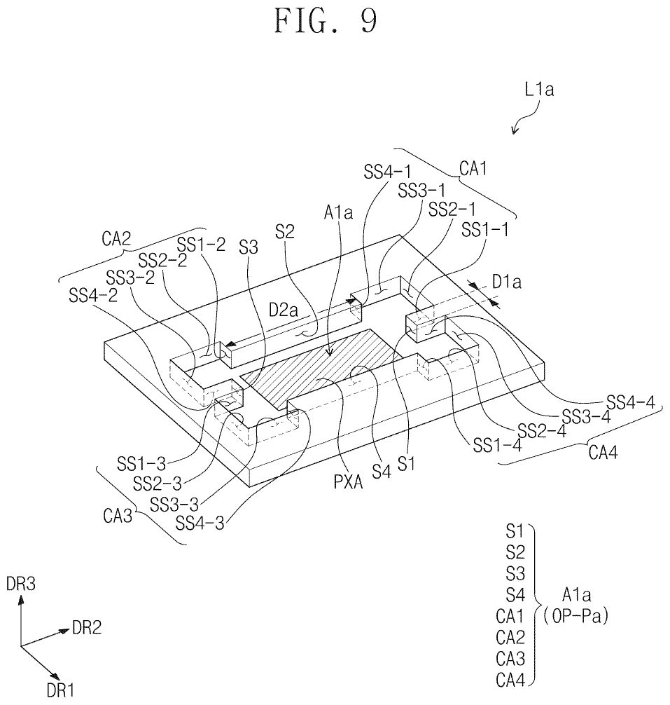

FIG. 9 is a perspective view of a first barrier wall layer L1a of the display panel DP (refer to FIG. 5) according to some embodiments of the present disclosure. For convenience of description, FIG. 9 is focused on a first region Ala of a barrier wall opening OP-Pa. In describing FIG. 9, the description will be made with reference to FIG. 8, and descriptions of the same reference numerals will be omitted.

Referring to FIGS. 5, 6, and 8, the first region Ala of the first barrier wall layer L1a may include a first inner surface S1, a second inner surface S2, a third inner surface S3, a fourth inner surface S4, a first corner region CA1, a second corner region CA2, a third corner region CA3, and a fourth corner region CA4.

In FIGS. 8 and 9, the distance between the first corner region CA1 and the fourth corner region CA4 may be defined as a first distance D1 or D1a, and the distance between the first corner region CA1 and the second corner region CA2 may be defined as a second distance D2 or D2a. The first distance D1 or D1a may correspond to the distance between the second corner region CA2 and the third corner region CA3, and the second distance D2 or D2a may correspond to the distance between the third corner region CA3 and the fourth corner region CA4.

The first distance D1a of FIG. 9 may be smaller than the first distance D1 of FIG. 8, and the second distance D2a of FIG. 9 may be smaller than the second distance D2 of FIG. 8. That is, the first to fourth corner regions CA1, CA2, CA3, and CA4 of FIG. 9 may be larger than the first to fourth corner regions CA1, CA2, CA3, and CA4 of FIG. 8.

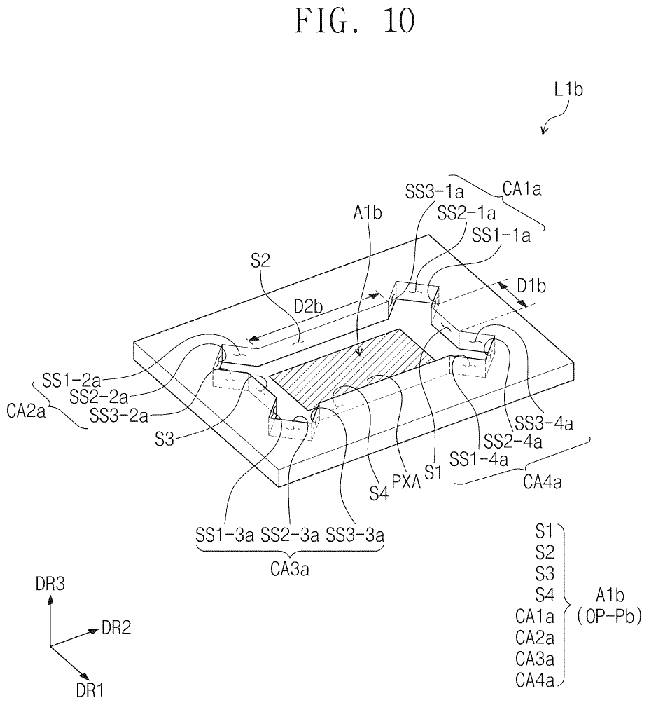

FIG. 10 is a perspective view of a first barrier wall layer L1b of the display panel DP (refer to FIG. 5) according to some embodiments of the present disclosure. For convenience of description, FIG. 10 is focused on a first region A1b of a barrier wall opening OP-Pb. In describing FIG. 10, the description will be made with reference to FIG. 8, and descriptions of the same reference numerals will be omitted.

Referring to FIGS. 5 and 10, the first region A1b of the first barrier wall layer L1b may include a first inner surface S1, a second inner surface S2, a third inner surface S3, and a fourth inner surface S4 and may include a first corner region CA1a, a second corner region CA2a, a third corner region CA3a, and a fourth corner region CA4a. The first corner region CA1a may connect the first inner surface S1 and the second inner surface S2, and the second corner region CA2a may connect the second inner surface S2 and the third inner surface S3. The third corner region CA3a may connect the third inner surface S3 and the fourth inner surface S4, and the fourth corner region CA4a may connect the fourth inner surface S4 and the first inner surface S1.

Each of the first to fourth corner regions CA1a, CA2a, CA3a, and CA4a may include a plurality of sub-inner surfaces. For example, the first to fourth corner regions CA1a, CA2a, CA3a, and CA4a may include first sub-inner surfaces SS1-1a, SS1-2a, SS1-3a, and SS1-4a, second sub-inner surfaces SS2-1a, SS2-2a, SS2-3a, and SS2-4a, and third sub-inner surfaces SS3-1a, SS3-2a, SS3-3a, and SS3-4a.

In detail, the first corner region CA1a may include the first sub-inner surface SS1-1a, the second sub-inner surface SS2-1a, and the third sub-inner surface SS3-1a. The first sub-inner surface SS1-1a may extend from the first inner surface S1 in a direction between the direction opposite to the first direction DR1 and the second direction DR2. The second sub-inner surface SS2-1a may extend from the first sub-inner surface SS1-1a in a direction between the direction opposite to the first direction DR1 and the direction opposite to the second direction DR2. The third sub-inner surface SS3-1a may extend from the second sub-inner surface SS2-1a in a direction between the first direction DR1 and the direction opposite to the second direction DR2. The third sub-inner surface SS3-1a may be connected with the second inner surface S2.

In the polygon defined by the first region A1b, when viewed from above the plane (e.g., in a plan view), the interior angle formed by the first sub-inner surface SS1-1a of the first corner region CA1a and the first inner surface S1 may be 180 degrees or more, and the interior angle formed by the third sub-inner surface SS3-1a of the first corner region CA1a and the second inner surface S2 may be 180 degrees or more. For example, the interior angle formed by the first sub-inner surface SS1-1a of the first corner region CA1a and the first inner surface S1 and the interior angle formed by the third sub-inner surface SS3-1a of the first corner region CA1a and the second inner surface S2 may be 225 degrees. Hereinafter, the interior angles in FIG. 10 will be described based on the polygon.

In addition, the interior angle formed by the first sub-inner surface SS1-1a and the second sub-inner surface SS2-1a of the first corner region CA1a may be 90 degrees, and the interior angle formed by the second sub-inner surface SS2-1a and the third sub-inner surface SS3-1a of the first corner region CA1a may be 90 degrees. However, the interior angles formed by the first sub-inner surface SS1-1a, the second sub-inner surface SS2-1a, and the third sub-inner surface SS3-1a are illustrative, and embodiments according to the present disclosure are not limited thereto.

The second corner region CA2a may include the first sub-inner surface SS1-2a, the second sub-inner surface SS2-2a, and the third sub-inner surface SS3-2a. The first sub-inner surface SS1-2a may extend from the second inner surface S2 in a direction between the direction opposite to the first direction DR1 and the direction opposite to the second direction DR2. The second sub-inner surface SS2-2a may extend from the first sub-inner surface SS1-2a in a direction between the first direction DR1 and the direction opposite to the second direction DR2. The third sub-inner surface SS3-2a may extend from the second sub-inner surface SS2-2a in a direction between the first direction DR1 and the second direction DR2. The third sub-inner surface SS3-2a may be connected with the third inner surface S3.

The interior angle formed by the first sub-inner surface SS1-2a of the second corner region CA2a and the second inner surface S2 may be 180 degrees or more, and the interior angle formed by the third sub-inner surface SS3-2a of the second corner region CA2a and the third inner surface S3 may be 180 degrees or more. For example, the int

erior angle formed by the first sub-inner surface SS1-2a of the second corner region CA2a and the second inner surface S2 and the interior angle formed by the third sub-inner surface SS3-2a of the second corner region CA2a and the third inner surface S3 may be 225 degrees.

In addition, the interior angle formed by the first sub-inner surface SS1-2a and the second sub-inner surface SS2-2a of the second corner region CA2a may be 90 degrees, and the interior angle formed by the second sub-inner surface SS2-2a and the third sub-inner surface SS3-2a of the second corner region CA2a may be 90 degrees. However, the interior angles formed by the first sub-inner surface SS1-2a, the second sub-inner surface SS2-2a, and the third sub-inner surface SS3-2a are illustrative, and embodiments according to the present disclosure are not limited thereto.

The third corner region CA3a may include the first sub-inner surface SS1-3a, the second sub-inner surface SS2-3a, and the third sub-inner surface SS3-3a. The first sub-inner surface SS1-3a may extend from the third inner surface S3 in a direction between the first direction DR1 and the direction opposite to the second direction DR2. The second sub-inner surface SS2-3a may extend from the first sub-inner surface SS1-3a in a direction between the first direction DR1 and the second direction DR2. The third sub-inner surface SS3-3a may extend from the second sub-inner surface SS2-3a in a direction between the direction opposite to the first direction DR1 and the second direction DR2. The third sub-inner surface SS3-3a may be connected with the fourth inner surface S4.

The interior angle formed by the first sub-inner surface SS1-3a of the third corner region CA3a and the third inner surface S3 may be 180 degrees or more, and the interior angle formed by the third sub-inner surface SS3-3a of the third corner region CA3a and the fourth inner surface S4 may be 180 degrees or more. For example, the interior angle formed by the first sub-inner surface SS1-3a of the third corner region CA3a and the third inner surface S3 and the interior angle formed by the third sub-inner surface SS3-3a of the third corner region CA3a and the fourth inner surface S4 may be 225 degrees.

In addition, the interior angle formed by the first sub-inner surface SS1-3a and the second sub-inner surface SS2-3a of the third corner region CA3a may be 90 degrees, and the interior angle formed by the second sub-inner surface SS2-3a and the third sub-inner surface SS3-3a of the third corner region CA3a may be 90 degrees. However, the interior angles formed by the first sub-inner surface SS1-3a, the second sub-inner surface SS2-3a, and the third sub-inner surface SS3-3a are illustrative, and embodiments according to the present disclosure are not limited thereto.

The fourth corner region CA4a may include the first sub-inner surface SS1-4a, the second sub-inner surface SS2-4a, and the third sub-inner surface SS3-4a. The first sub-inner surface SS1-4a may extend from the fourth inner surface S4 in a direction between the first direction DR1 and the second direction DR2. The second sub-inner surface SS2-4a may extend from the first sub-inner surface SS1-4a in a direction between the direction opposite to the first direction DR1 and the second direction DR2. The third sub-inner surface SS3-4a may extend from the second sub-inner surface SS2-4a in a direction between the direction opposite to the first direction DR1 and the direction opposite to the second direction DR2. The third sub-inner surface SS3-4a may be connected with the first inner surface S1.

The interior angle formed by the first sub-inner surface SS1-4a of the fourth corner region CA4a and the fourth inner surface S4 may be 180 degrees or more, and the interior angle formed by the third sub-inner surface SS3-4a of the fourth corner region CA4a and the first inner surface S1 may be 180 degrees or more. For example, the interior angle formed by the first sub-inner surface SS1-4a of the fourth corner region CA4a and the fourth inner surface S4 and the interior angle formed by the third sub-inner surface SS3-4a of the fourth corner region CA4a and the first inner surface S1 may be 225 degrees.

In addition, the interior angle formed by the first sub-inner surface SS1-4a and the second sub-inner surface SS2-4a of the fourth corner region CA4a may be 90 degrees, and the interior angle formed by the second sub-inner surface SS2-4a and the third sub-inner surface SS3-4a of the fourth corner region CA4a may be 90 degrees. However, the interior angles formed by the first sub-inner surface SS1-4a, the second sub-inner surface SS2-4a, and the third sub-inner surface SS3-4a are illustrative, and embodiments according to the present disclosure are not limited thereto.

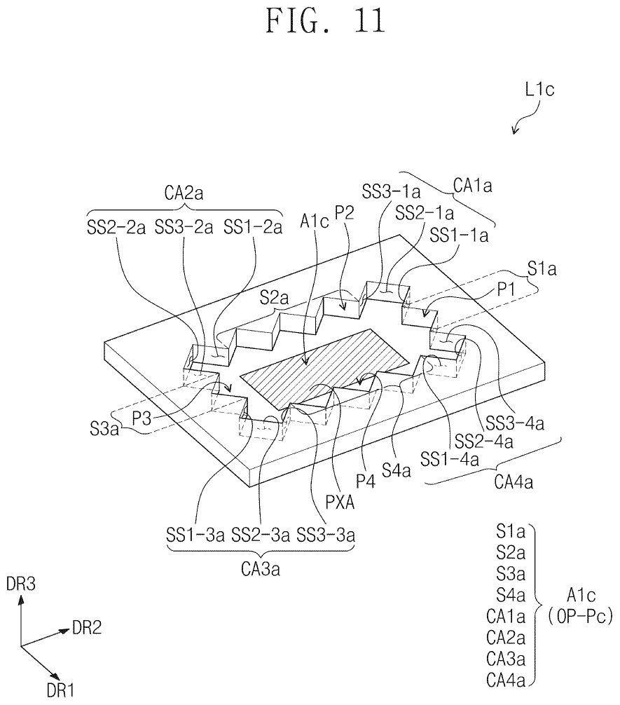

FIG. 11 is a perspective view of a first barrier wall layer L1c of the display panel DP (refer to FIG. 5) according to some embodiments of the present disclosure. For convenience of description, FIG. 11 is focused on a first region A1c of a barrier wall opening OP-Pc. In describing FIG. 11, the description will be made with reference to FIG. 10, and descriptions of the same reference numerals will be omitted.

Referring to FIG. 11, the first region A1c of the first barrier wall layer L1c may include a first inner surface S1a, a second inner surface S2a, a third inner surface S3a, and a fourth inner surface S4a and may include a first corner region CA1a, a second corner region CA2a, a third corner region CA3a, and a fourth corner region CA4a.

The first inner surface Sa, the second inner surface S2a, the third inner surface S3a, and the fourth inner surface S4a may correspond to the inner surface S-L1 of the first barrier wall layer L1 of FIG. 5. The first inner surface S1a and the third inner surface S3a may extend in a direction parallel to the first direction DR1, and the second inner surface S2a and the fourth inner surface S4a may extend in a direction parallel to the second direction DR2.

The first inner surface S1a, the second inner surface S2a, the third inner surface S3a, and the fourth inner surface S4a may include protruding regions P1, P2, P3, and P4, respectively, each of which includes a plurality of sub-inner surfaces. For example, the first inner surface S1a may include the first protruding region P1, the second inner surface S2a may include the second protruding region P2, the third inner surface S3a may include the third protruding region P3, and the fourth inner surface S4a may include the fourth protruding region P4.

The plurality of sub-inner surfaces of each of the protruding regions P1, P2, P3, and P4 may extend in directions away from the center of the barrier wall opening OP-Pc. For example, the plurality of sub-inner surfaces of the first to fourth protruding regions P1, P2, P3, and P4 may extend in a direction between the first direction DR1 and the second direction DR2 or in a direction between the direction opposite to the first direction DR1 and the second direction DR2. Each of the first protruding region P1 and the third protruding region P3 may include one inner surface extending in the direction between the first direction DR1 and the second direction DR2 and one inner surface extending in the direction between the direction opposite to the first direction DR1 and the second direction DR2. Each of the second protruding region P2 and the fourth protruding region P4 may include three inner surfaces extending in the direction between the first direction DR1 and the second direction DR2 and three inner surfaces extending in the direction between the direction opposite to the first direction DR1 and the second direction DR2. However, the shapes of the first to fourth protruding regions P1, P2, P3, and P4 illustrated in FIG. 11, that is, the number and directions of inner surfaces are illustrative, and embodiments according to the present disclosure are not limited thereto.

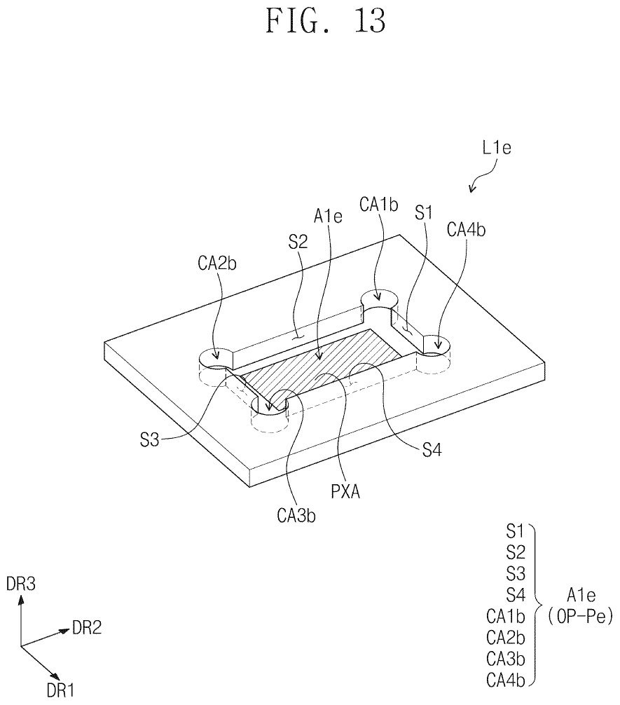

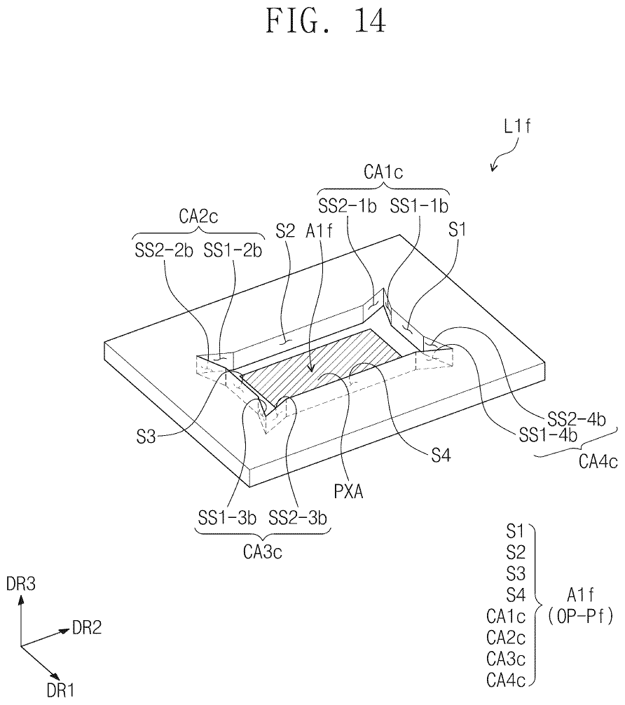

The first corner region CA1a may connect the first inner surface S1a and the second inner surface S2a, and the second corner region CA2a may connect the second inner surface S2a and the third inner surface S3a. The third corner region CA3a may connect the third inner surface S3a and the fourth inner surface S4a, and the fourth corner region CA4a may connect the fourth inner surface S4a and the first inner surface S1a. The first to fourth corner regions CA1a, CA2a, CA3a, and CA4a of FIG. 11 may be substantially similar to the first to fourth corner regions CA1a, CA2a, CA3a, and CA4a of FIG. 10. However, without being limited thereto, the first to fourth corner regions CA1a, CA2a, CA3a, and CA4a of FIG. 11 may have the shape of the first to fourth corner regions CA1, CA2, CA3, and CA4 of FIGS. 8 and 9, the shape of first to fourth corner regions CA1b, CA2b, CA3b, and CA4b of FIG. 13, or the shape of first to fourth corner regions CA1c, CA2c, CA3c, and CA4c of FIG. 14.

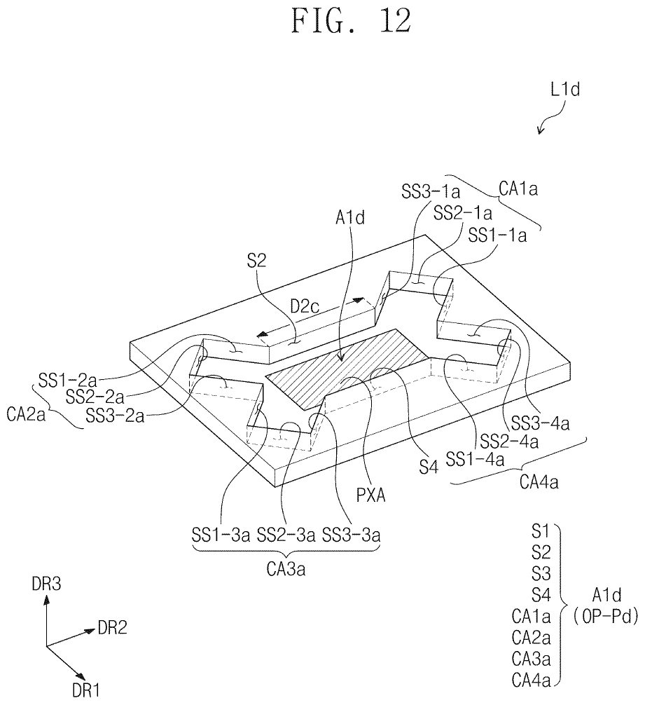

FIG. 12 is a perspective view of a first barrier wall layer L1d of the display panel DP (refer to FIG. 5) according to some embodiments of the present disclosure. For convenience of description, FIG. 12 is focused on a first region A1d of a barrier wall opening OP-Pd. In describing FIG. 12, the description will be made with reference to FIG. 10, and descriptions of the same reference numerals will be omitted.

Referring to FIGS. 5, 10, and 12, the first region Ala of the first barrier wall layer L1a may include a first inner surface S1, a second inner surface S2, a third inner surface S3, a fourth inner surface S4, a first corner region CA1a, a second corner region CA2a, a third corner region CA3a, and a fourth corner region CA4a.

In FIG. 10, the distance between the first corner region CA1a and the fourth corner region CA4a may be defined as a first distance D1b, and in FIGS. 10 and 12, the distance between the first corner region CA1a and the second corner region CA2a may be defined as a second distance D2b or D2c. The first distance D1b of FIG. 10 may correspond to the distance between the second corner region CA2a and the third corner region CA3a of FIG. 10, and the second distance D2b or D2c of FIGS. 10 and 12 may correspond to the distance between the third corner region CA3a and the fourth corner region CA4a of FIGS. 10 and 12.

The first corner region CA1a and the fourth corner region CA4a of FIG. 12 may be formed to make contact with each other. That is, the distance between the first corner region CA1a and the fourth corner region CA4a may be 0, and the distance between the first corner region CA1a and the fourth corner region CA4a of FIG. 12 may be smaller than the first distance D1b of FIG. 10. In addition, the second distance D2c of FIG. 12 may be smaller than the second distance D2b of FIG. 10. That is, the first to fourth corner regions CA1a, CA2a, CA3a, and CA4a of FIG. 12 may be larger than the first to fourth corner regions CA1a, CA2a, CA3a, and CA4a of FIG. 10.

FIG. 13 is a perspective view of a first barrier wall layer L1e of the display panel DP (refer to FIG. 5) according to some embodiments of the present disclosure. For convenience of description, FIG. 13 is focused on a first region Ale of a barrier wall opening OP-Pe. In describing FIG. 13, the description will be made with reference to FIG. 8, and descriptions of the same reference numerals will be omitted.

Referring to FIGS. 5 and 13, the first region Ale of the first barrier wall layer L1e may include a first inner surface S1, a second inner surface S2, a third inner surface S3, and a fourth inner surface S4 and may include the first corner region CA1b, the second corner region CA2b, the third corner region CA3b, and the fourth corner region CA4b. The first corner region CA1b may connect the first inner surface S1 and the second inner surface S2, and the second corner region CA2b may connect the second inner surface S2 and the third inner surface S3. The third corner region CA3b may connect the third inner surface S3 and the fourth inner surface S4, and the fourth corner region CA4b may connect the fourth inner surface S4 and the first inner surface S1.

Each of the first to fourth corner regions CA1b, CA2b, CA3b, and CA4b may have the shape of a portion of a circle. For example, when viewed from above the plane (e.g., in a plan view), the first corner region CA1b may have an arc shape that connects the first inner surface S1 and the second inner surface S2. When viewed from above the plane (e.g., in a plan view), the second corner region CA2b may have an arc shape that connects the second inner surface S2 and the third inner surface S3. When viewed from above the plane (e.g., in a plan view), the third corner region CA3b may have an arc shape that connects the third inner surface S3 and the fourth inner surface S4. When viewed from above the plane (e.g., in a plan view), the fourth corner region CA4b may have an arc shape that connects the fourth inner surface S4 and the first inner surface S1.

FIG. 14 is a perspective view of a first barrier wall layer L1f of the display panel DP (refer to FIG. 5) according to some embodiments of the present disclosure. For convenience of description, FIG. 14 is focused on a first region Alf of a barrier wall opening OP-Pf. In describing FIG. 14, the description will be made with reference to FIG. 8, and descriptions of the same reference numerals will be omitted.

Referring to FIGS. 5 and 14, the first region Alf of the first barrier wall layer L1f may include a first inner surface S1, a second inner surface S2, a third inner surface S3, and a fourth inner surface S4 and may include the first corner region CA1c, the second corner region CA2c, the third corner region CA3c, and the fourth corner region CA4c. The first corner region CA1c may connect the first inner surface S1 and the second inner surface S2, and the second corner region CA2c may connect the second inner surface S2 and the third inner surface S3. The third corner region CA3c may connect the third inner surface S3 and the fourth inner surface S4, and the fourth corner region CA4c may connect the fourth inner surface S4 and the first inner surface S1.

Each of the first to fourth corner regions CA1c, CA2c, CA3c, and CA4c may include a plurality of sub-inner surfaces. For example, the first to fourth corner regions CA1c, CA2c, CA3c, and CA4c may include first sub-inner surfaces SS1-1b, SS1-2b, SS1-3b, and SS1-4b and second sub-inner surfaces SS2-1b, SS2-2b, SS2-3b, and SS2-4b.

In detail, the first corner region CA1c may include the first sub-inner surface SS1-1b and the second sub-inner surface SS2-1b. The first sub-inner surface SS1-1b may extend from the first inner surface S1 in a direction between the direction opposite to the first direction DR1 and the second direction DR2. The second sub-inner surface SS2-1b may extend from the first sub-inner surface SS1-1b in a direction between the first direction DR1 and the direction opposite to the second direction DR2. The second sub-inner surface SS2-1b may be connected with the second inner surface S2.

In the polygon defined by the first region A1f, when viewed from above the plane (e.g., in a plan view), the interior angle formed by the first sub-inner surface SS1-1b of the first corner region CA1c and the first inner surface S1 may be 180 degrees or more, and the interior angle formed by the second sub-inner surface SS2-1b of the first corner region CA1c and the second inner surface S2 may be 180 degrees or more. In addition, the interior angle formed by the first sub-inner surface SS1-1b and the second sub-inner surface SS2-1b of the first corner region CA1c may be 90 degrees or less. However, the interior angles formed by the first sub-inner surface SS1-1b and the second sub-inner surface SS2-1b are illustrative, and embodiments according to the present disclosure are not limited thereto. Hereinafter, the interior angles in FIG. 14 will be described based on the polygon.

The second corner region CA2c may include the first sub-inner surface SS1-2b and the second sub-inner surface SS2-2b. The first sub-inner surface SS1-2b may extend from the second inner surface S2 in a direction between the direction opposite to the first direction DR1 and the direction opposite to the second direction DR2. The second sub-inner surface SS2-2b may extend from the first sub-inner surface SS1-2b in a direction between the first direction DR1 and the second direction DR2. The second sub-inner surface SS2-2b may be connected with the third inner surface S3.

The interior angle formed by the first sub-inner surface SS1-2b of the second corner region CA2c and the second inner surface S2 may be 180 degrees or more, and the interior angle formed by the second sub-inner surface SS2-2b of the second corner region CA2c and the third inner surface S3 may be 180 degrees or more. In addition, the interior angle formed by the first sub-inner surface SS1-2b and the second sub-inner surface SS2-2b of the second corner region CA2c may be 90 degrees or less. However, the interior angles formed by the first sub-inner surface SS1-2b and the second sub-inner surface SS2-2b are illustrative, and embodiments according to the present disclosure are not limited thereto.

The third corner region CA3c may include the first sub-inner surface SS1-3b and the second sub-inner surface SS2-3b. The first sub-inner surface SS1-3b may extend from the third inner surface S3 in a direction between the first direction DR1 and the direction opposite to the second direction DR2. The second sub-inner surface SS2-3b may extend from the first sub-inner surface SS1-3b in a direction between the direction opposite to the first direction DR1 and the second direction DR2. The second sub-inner surface SS2-3b may be connected with the fourth inner surface S4.

The interior angle formed by the first sub-inner surface SS1-3b of the third corner region CA3c and the third inner surface S3 may be 180 degrees or more, and the interior angle formed by the second sub-inner surface SS2-3b of the third corner region CA3c and the fourth inner surface S4 may be 180 degrees or more. In addition, the interior angle formed by the first sub-inner surface SS1-3b and the second sub-inner surface SS2-3b of the third corner region CA3c may be 90 degrees or less. However, the interior angles formed by the first sub-inner surface SS1-3b and the second sub-inner surface SS2-3b are illustrative, and embodiments according to the present disclosure are not limited thereto.

The fourth corner region CA4c may include the first sub-inner surface SS1-4b and the second sub-inner surface SS2-4b. The first sub-inner surface SS1-4b may extend from the fourth inner surface S4 in a direction between the first direction DR1 and the second direction DR2. The second sub-inner surface SS2-4b may extend from the first sub-inner surface SS1-4b in a direction between the direction opposite to the first direction DR1 and the direction opposite to the second direction DR2. The second sub-inner surface SS2-4b may be connected with the first inner surface S1.

The interior angle formed by the first sub-inner surface SS1-4b of the fourth corner region CA4c and the fourth inner surface S4 may be 180 degrees or more, and the interior angle formed by the second sub-inner surface SS2-4b of the fourth corner region CA4c and the first inner surface S1 may be 180 degrees or more. In addition, the interior angle formed by the first sub-inner surface SS1-4b and the second sub-inner surface SS2-4b of the fourth corner region CA4c may be 90 degrees or less. However, the interior angles formed by the first sub-inner surface SS1-4b and the second sub-inner surface SS2-4b are illustrative, and embodiments according to the present disclosure are not limited thereto.

Referring to FIGS. 6 and 8 to 14, the barrier wall openings OP1-P, OP2-P, and OP3-P of the present disclosure may further include the extended corner regions. Accordingly, even though the shadow regions are formed in the barrier wall PW, the contact areas of the cathodes CE1, CE2, and CE3 may be larger than or equal to the effective contact areas, and thus defects in the light emitting elements ED1, ED2, and ED3 may be reduced or eliminated.

As described above, the barrier wall openings according to some embodiments of the present disclosure may further include the extended corner regions. Accordingly, even though the shadow regions are formed in the barrier wall, the contact areas of the cathodes may be larger than or equal to the effective contact areas, and thus defects in the light emitting elements may be reduced or eliminated.

While aspects of some embodiments of the present disclosure have been described with reference to some embodiments thereof, it will be apparent to those of ordinary skill in the art that various changes and modifications may be made thereto without departing from the spirit and scope of embodiments according to the present disclosure as set forth in the following claims, and their equivalents.

What is claimed is:

1. A display panel comprising:
a base layer;
a pixel defining layer on the base layer, the pixel defining layer having a light emitting opening;
a barrier wall on the pixel defining layer, the barrier wall having a barrier wall opening overlapping the light emitting opening; and
a light emitting element including an anode, an intermediate layer, and a cathode contacting the barrier wall,
wherein the barrier wall opening includes:
a first inner surface and a third inner surface extending in a direction parallel to a first direction;
a second inner surface and a fourth inner surface extending in a direction parallel to a second direction crossing the first direction;
a first corner region connecting the first inner surface and the second inner surface;
a second corner region connecting the second inner surface and the third inner surface;
a third corner region connecting the third inner surface and the fourth inner surface; and
a fourth corner region connecting the fourth inner surface and the first inner surface.

2. The display panel of claim 1, wherein each of the first to fourth corner regions includes a plurality of sub-inner surfaces, and an interior angle formed by the first inner surface and at least one sub-inner surface adjacent to the first inner surface among the plurality of sub-inner surfaces is 180 degrees or more.

3. The display panel of claim 1, wherein, in a plan view, the first corner region has an arc shape connecting the first inner surface and the second inner surface.

4. The display panel of claim 1, wherein the first corner region includes:
a first sub-inner surface extending from the first inner surface; and
a second sub-inner surface extending from the first sub-inner surface and connected with the second inner surface.

5. The display panel of claim 4, wherein an interior angle formed by the first sub-inner surface and the first inner surface is 180 degrees or more, and an interior angle formed by the second sub-inner surface and the second inner surface is 180 degrees or more.

6. The display panel of claim 1, wherein the first corner region includes:
a first sub-inner surface extending from the first inner surface;
a second sub-inner surface extending from the first sub-inner surface; and
a third sub-inner surface extending from the second sub-inner surface and connected with the second inner surface.

7. The display panel of claim 6, wherein an interior angle formed by the first sub-inner surface and the first inner surface is 180 degrees or more, and an interior angle formed by the third sub-inner surface and the second inner surface is 180 degrees or more.

8. The display panel of claim 6, wherein an interior angle formed by the first sub-inner surface and the second sub-inner surface is 90 degrees, and an interior angle formed by the second sub-inner surface and the third sub-inner surface is 90 degrees.

9. The display panel of claim 1, wherein the first corner region includes:
a first sub-inner surface extending from the first inner surface;
a second sub-inner surface extending from the first sub-inner surface;
a third sub-inner surface extending from the second sub-inner surface; and
a fourth sub-inner surface extending from the third sub-inner surface and connected with the second inner surface.

10. The display panel of claim 9, wherein an interior angle formed by the first sub-inner surface and the first inner surface is 180 degrees or more, and an interior angle formed by the fourth sub-inner surface and the second inner surface is 180 degrees or more.

11. The display panel of claim 9, wherein an interior angle formed by the first sub-inner surface and the second sub-inner surface is 90 degrees, an interior angle formed by the second sub-inner surface and the third sub-inner surface is 90 degrees, and an interior angle formed by the third sub-inner surface and the fourth sub-inner surface is 90 degrees.

12. The display panel of claim 1, wherein the first to fourth inner surfaces include protruding regions, respectively, each of which includes a plurality of sub-inner surfaces, and the plurality of sub-inner surfaces extend in directions away from a center of the barrier wall opening.

13. A display panel comprising:
a base layer;
a pixel defining layer on the base layer, the pixel defining layer having a light emitting opening;
a barrier wall on the pixel defining layer, the barrier wall having a barrier wall opening configured to overlap the light emitting opening; and
a light emitting element including an anode, an intermediate layer, and a cathode contacting the barrier wall,
wherein the barrier wall opening includes:
a first inner surface and a third inner surface extending in a direction parallel to a first direction;
a second inner surface and a fourth inner surface extending in a direction parallel to a second direction crossing the first direction; and
corner regions connecting the first to fourth inner surfaces and extending in directions away from a center of the barrier wall opening.

14. The display panel of claim 13, wherein the corner regions include:
a first corner region connecting the first inner surface and the second inner surface;
a second corner region connecting the second inner surface and the third inner surface;
a third corner region connecting the third inner surface and the fourth inner surface; and
a fourth corner region connecting the fourth inner surface and the first inner surface.

15. The display panel of claim 14, wherein each of the first to fourth corner regions includes a plurality of sub-inner surfaces, and an interior angle formed by the first inner surface and at least one sub-inner surface adjacent to the first inner surface among the plurality of sub-inner surfaces is 180 degrees or more.

16. The display panel of claim 14, wherein, in a plan view, the first corner region has an arc shape configured to connect the first inner surface and the second inner surface.

17. The display panel of claim 14, wherein the first corner region includes:
a first sub-inner surface extending from the first inner surface; and
a second sub-inner surface extending from the first sub-inner surface and connected with the second inner surface.

18. The display panel of claim 14, wherein the first corner region includes:
a first sub-inner surface extending from the first inner surface;
a second sub-inner surface extending from the first sub-inner surface; and
a third sub-inner surface extending from the second sub-inner surface and connected with the second inner surface.

19. The display panel of claim 14, wherein the first corner region includes:
a first sub-inner surface extending from the first inner surface;
a second sub-inner surface extending from the first sub-inner surface;
a third sub-inner surface extending from the second sub-inner surface; and
a fourth sub-inner surface extending from the third sub-inner surface and connected with the second inner surface.

20. The display panel of claim 14, wherein the first to fourth inner surfaces include protruding regions, respectively, each of which includes a plurality of sub-inner surfaces, and the plurality of sub-inner surfaces extend in directions away from the center of the barrier wall opening.
